(19) United States
(12) Patent Application Publication
(10) Pub. No.: US 2026/0286504 A1
(43) Pub. Date: Sep. 24, 2026

(54) DEVICE, CONTROL DEVICE AND METHOD FOR LASER-INDUCED ARC EVAPORATION

(71) Applicant: VON ARDENNE ASSET GMBH & CO. KG, Dresden (DE)

(72) Inventors: Carsten Deus, Dresden (DE); Barbara Gebhardt, Heidenau (DE); Ruben Seifert, Dresden (DE); Martin Kopte, Freital (DE); Marc Tobias Wenzel, Dresden (DE)

(21) Appl. No.: 19/474,544

(22) PCT Filed: May 13, 2024
(86) PCT No.: PCT/DE2024/100422

§ 371 Date: Oct. 10, 2025

(30) Foreign Application Priority Data
May 19, 2023 (DE) 10 2023 113 197.4

(51) Int. Cl. C23C 14/32; C23C 14/54; H05H 1/48

(52) U.S. Cl. CPC C23C 14/325; C23C 14/54; H05H 1/48

(57) ABSTRACT

A method comprising controlling a laser source and an electrical power source per an operating sequence. The operating sequence comprises several phases, in each: the laser source generates an excitation pulse directed at a target to excite an arc discharge at the target, the power source generates a first electrical power pulse to electrically power the arc discharge, and/or the power source generates a second electrical power pulse is generated by the power source to accelerate a material flow released from the target by the arc discharge away from the target. The plurality of phases comprise: one or more than one first phase, in each first phase of which the first power pulse and/or the second power pulse are generated per excitation pulse, and a second phase in which two excitation pulses and/or two first electrical power pulses are generated per second electrical power pulse.

### CROSS-REFERENCE TO RELATED APPLICATIONS

This application is a U.S. national stage filing under 35 U.S.C. § 371 of International Patent Application No. PCT/DE2024/100422, filed May 13, 2024, which international application claims the benefit of and priority to German Application No. 10 2023 113 197.4, filed May 19, 2023, the entire contents of these applications are incorporated herein by reference.

### TECHNICAL FIELD

Various embodiments relate to an apparatus, such as a vacuum assembly, a control apparatus, and a method for laser-induced arc evaporation.

### BACKGROUND

In general, a substrate (e.g., a workpiece) may be coated so that the chemical and/or physical properties of the substrate may be changed. The coating of the substrate may be carried out in a vacuum, in which one or more layers are deposited on the substrate by physical vapor deposition. An economically and technically attractive process for physical vapor deposition is known as arc evaporation, in which a material is evaporated by an arc discharge. However, only a few materials and layer architectures are currently suitable for arc evaporation, which is why the potential of arc evaporation cannot usually be fully exploited. This applies analogously to other types of evaporation using plasma, for which arc evaporation is referred to here as an example.

### SUMMARY

The task arising from this background is solved by various embodiments provided herein and aspects explained herein.

According to various embodiments, a method may comprise: controlling a laser source and an electrical power source according to an operating sequence; wherein the operating sequence comprises several phases, in each of which: the laser source generates an excitation pulse directed at a target to excite an arc discharge at the target, the electrical power source generates a first electrical power pulse to electrically power the arc discharge, and/or the electrical power source generates a second electrical power pulse is generated by the electrical power source to accelerate a material flow released from the target by the arc discharge away from the target; wherein the plurality of phases comprise: one or more than one first phase, in each first phase of which the first electrical power pulse and/or the second electrical power pulse are generated per excitation pulse, and a second phase in which two excitation pulses and/or two first electrical power pulses are generated per second electrical power pulse.

According to various embodiments, it has been recognized that arc evaporation offers additional leeway in the selection of the operating point in order to influence the properties of the resulting coating, especially when there are additional conflicting requirements. These include, for example, requirements due to a temperature-sensitive substrate, requirements for the properties of the coating, and/or requirements for productivity.

Various embodiments relate to a device, such as a vacuum arrangement, a control device, and a method (e.g., for laser-induced arc evaporation), which increase the scope for selecting the operating point (OP) of the arc evaporation.

This makes it easier, for example, to reduce the effects of arc evaporation, such as a high evaporation rate and/or a high degree of excitation and/or ionization of the resulting material vapor. This makes it easier, for example, to reduce the energy input into the substrate (e.g., a bipolar plate) when coating it (e.g., with carbon), so that excessive heating of the substrate is inhibited and the associated losses in layer properties and/or productivity are minimized.

Various examples are described below that relate to what is described herein and shown in the figures.

For ease of understanding, reference is made to a laser-excited arc discharge (also known as a laser-induced arc discharge) as an example of a pulse-excited plasma discharge in which an arc discharge is excited by a laser pulse. The description provided here may be understood as analogous to any other type of pulse-excited plasma discharge, which does not necessarily have to be an arc discharge and/or does not necessarily have to be excited by a laser pulse (see examples 53 and 54 below), for example, pulsed sputtering or similar.

Example 1 is a method (e.g., for performing laser-induced arc evaporation) comprising: controlling an excitation source (e.g., laser source) according to an operating sequence (e.g., implemented by code segments, e.g., stored); controlling an electrical power source according to the operating sequence; wherein the operating sequence preferably comprises several phases, in each of which preferably: an excitation pulse (e.g., laser pulse) directed at a target is generated by the excitation source (e.g., laser source) in order to excite a plasma discharge (e.g., arc discharge) at the target; a first electrical power pulse is generated by the power source to electrically supply the plasma discharge (e.g., arc discharge) by the target; and/or a second electrical power pulse is generated by the power source to accelerate (e.g., the ionized portion) a material flow released from the target by the plasma discharge (e.g., arc discharge) away from the target and/or toward a substrate holder (e.g., by which, for example, a bipolar plate is held).

An operating sequence is understood here to be a specification according to which one or more than one manipulation member, which is configured to influence the generation of the plasma discharge (e.g., arc discharge), is controlled. The operating sequence may specify one or more setpoint parameters according to which the first and/or second power pulse and/or the excitation pulse (e.g., laser pulse) are generated. Examples of such parameters include frequency, total power, pulse shape, pulse duration, (temporal) delay (e.g., a time offset) of a pulse, etc.

Example 2 is configured according to Example 1, wherein the first electrical power pulse is transmitted by the target and/or an anode associated with the target; and/or wherein the second electrical power pulse is transmitted by a substrate holder onto which the material flow is directed and/or an anode associated with the substrate holder. For example, a reference potential, such as electrical ground (also referred to as ground potential), may be applied to the anode.

Example 3 is configured according to Example 1 or 2, wherein the plurality of phases comprise one or more than one first phase (also referred to as phase of the first type), in each first phase of which the first electrical power pulse and/or the second electrical power pulse are generated per excitation pulse (e.g., laser pulse), and comprising a second phase (also referred to as a second type phase), in which at least two (i.e., two or more than two) excitation pulses (e.g., laser pulses) and/or at least two (i.e., two or more than two) first electrical power pulses are generated per second electrical power pulse.

Example 4 is configured according to Example 3, wherein the plurality of phases per second phase comprises at least two or three first phases.

Example 5 is configured according to one of Examples 1 to 4, wherein the first electrical power pulse is generated according to a target pulse length that is in a range from approximately 30 μs to approximately 600 μs, preferably in a range from approximately 150 μs to approximately 350 μs.

Example 6 is configured according to one of examples 1 to 5, wherein the first electrical power pulse is generated according to a target pulse length that is in a range from approximately 250 μs to approximately 350 μs.

Example 7 is configured according to one of examples 1 to 6, wherein the first electrical power pulse is generated according to a target current pulse (e.g., amplitude, duration, gradient, etc.); and/or wherein the second electrical power pulse is generated according to a target voltage pulse (e.g., amplitude, duration, gradient, etc.).

Example 8 is configured according to one of examples 1 to 7, wherein each phase of the operating sequence is configured such that the first electrical power pulse is generated according to a target pulse frequency, wherein a ratio of the target pulse frequency to an actual length of the target is in a range of approximately 400 Hz/m (e.g., 750 Hz/m) to approximately 2500 Hz/m (e.g., 2000 Hz/m), preferably in a range of approximately 1200 Hz/m to approximately 2000 Hz/m, and more preferably in a range of approximately 1200 Hz/m to approximately 1600 Hz/m.

Example 9 is configured according to one of the examples, wherein the second electrical power pulse includes a target peak value in a range from approximately 300 V to approximately 1500 V (e.g., 1000 V), preferably in a range from approximately 500 V to approximately 1000 V, and further preferably in a range from approximately 700 V to approximately 900 V.

Example 10 is configured according to one of examples 1 to 9, wherein the first electrical power pulse is generated according to a target pulse shape (as a target time dependence of the power), which is, for example, a sine pulse shape, a square pulse shape, or a triangular pulse shape (see also FIG. 3) and/or includes an asymmetrical pulse shape.

For example, the peak value of an asymmetrical triangular pulse shape may be reached after approximately 65% of the pulse duration. Alternatively, or additionally, the falling edge of an asymmetrical pulse shape may be as short as possible.

The contribution of the falling edge to the integrated current of an asymmetric pulse (also referred to as the current pulse integral) may, for example, be smaller than the contribution of the rising edge to the current pulse integral (e.g., approximately 50% thereof). The contribution of the falling edge to the integrated power of an asymmetric pulse (also referred to as the power pulse integral) may, for example, be less than the contribution of the rising edge to the power pulse integral (e.g., approximately 25% thereof).

A triangular pulse shape is understood to be a time dependence of the pulse in which the rising edge and/or the falling edge of the pulse have a constant gradient (e.g., the same gradient). The peak value may also, but does not necessarily have to, be reached after half the pulse duration of the pulse.

A sine wave pulse shape is understood to be a time dependence of the pulse which may essentially be described by a sine function. For example, the rising edge and/or the falling edge in the direction of the peak value may have a decreasing gradient which, for example, approaches zero towards the peak value.

Example 11 is configured according to Example 10, wherein the electrical power source includes an output filter that is configured to be controlled in response to the desired pulse shape to influence a time dependence of the electrical power pulse.

Example 12 is configured according to one of examples 1 to 11, wherein the first electrical power pulse is generated according to a desired time dependence which includes a gradient in a range from approximately 5·MA/s (megaamperes per second) to approximately 150·MA/s, e.g., 5·MA/s to approximately 70·MA/s, e.g., 10·MA/s to approximately 24·MA/s.

Example 13 is configured according to one of Examples 1 to 12, wherein the target comprises or consists of carbon.

Example 14 is configured according to one of examples 1 to 13, wherein in at least one (e.g., each) phase of the plurality of phases, a first electrical power pulse and a second electrical power pulse are generated, which only partially overlap each other (in time).

Example 15 is configured according to Example 14, wherein, in the at least one (e.g., each) phase of the multiple phases, the second electrical power pulse is generated with a time offset (also referred to as a target time offset and/or target time delay) relative to the first electrical power pulse; and/or wherein, in the at least one (e.g., each) phase of the plurality of phases, the first electrical power pulse is generated according to a first target time difference (also referred to as a first target time delay) (e.g., a first target time delay=0) from a start of the at least one phase, and wherein the second electrical power pulse is generated according to a second target time difference (also referred to as a second target time delay) (e.g., a second target time delay >0, for example up to 500 μs, e.g., up to 100 μs) from the start of the at least one phase, wherein the second target time difference is greater than the first target time difference. Alternatively, or additionally, the target interval may correspond to twice the time duration of the first power pulse.

Illustratively, the second electrical power pulse in the at least one phase may begin before or after the first electrical power pulse.

Example 16 is configured according to Example 14 or 15, wherein the second electrical power pulse (e.g., according to a target time offset) is generated in the at least one phase after the first electrical power pulse.

Example 17 is configured according to one of examples 14 to 16, wherein the first electrical power pulse is generated according to a first target pulse duration, and the second electrical power pulse is generated according to a second target pulse duration such that the second electrical power pulse ends (in time) before the first electrical power pulse.

Example 18 is configured according to one of examples 14 to 17, wherein the first electrical power pulse and the second electrical power pulse are generated such that the second electrical power pulse begins after the first electrical power pulse and/or ends before the first electrical power pulse.

Example 19 is a computer program configured, when executed by a processor, to cause the processor to perform the method according to any of examples 1 to 18.

Example 20 is a computer-readable medium that stores instructions that, when executed by a processor, cause the processor to perform the method according to any of examples 1 to 18.

Example 21 is a control device comprising one or more processors configured to perform the method according to any one of examples 1 to 18.

Example 22 is an apparatus (e.g., a vacuum assembly) comprising: the control device according to Example 21; the power source; the excitation source (e.g., laser source); and a target holder for holding the target, wherein the target holder is electrically coupled to the power source; wherein the target holder optionally provides a rotational axis and is configured to cause the target to rotate about the rotational axis.

Example 23 is configured according to Example 22, further comprising: a vacuum chamber coupled to the excitation source (e.g., laser source) and the power source, and in which the target holder is disposed.

Example 24 is configured according to Example 22 or 23, further comprising: the substrate holder coupled to the power source and optionally disposed in the vacuum chamber.

Example 25 is configured according to Example 24, wherein a distance between the axis of rotation (or a target held in the target holder) and the substrate holder is in a range of approximately 200 mm (e.g., 410 mm) to approximately 750 mm or less.

Example 26 is configured according to one of examples 22 to 25, further comprising: a transport device for transporting a substrate along a transport path past the target holder.

Example 27 is configured according to one of examples 22 to 26, further comprising: a particle filter disposed between the target holder and the substrate holder and configured to filter the stream of material released from the target by the plasma discharge (e.g., arc discharge).

Example 28 is configured according to one of examples 22 to 27, further comprising: an anode coupled to the power source.

Example 29 is configured according to one of examples 22 to 28, wherein the target holder is configured to drive the rotational movement (e.g., wherein the target holder includes a drive, e.g., an electric motor, which is configured to apply torque to the target).

Example 30 is configured according to Example 29, wherein a (e.g., target) frequency of the rotational movement is in a range of approximately 10 revolutions per minute to approximately 40 revolutions per minute, preferably in a range of approximately 20 revolutions per minute to approximately 30 revolutions per minute.

Example 31 is a method comprising: disposing (e.g., transporting) a (e.g., metallic) bipolar plate in a vacuum; and performing pulse-induced (e.g., laser-induced) arc evaporation (e.g., as a plasma discharge) in the vacuum by controlling an excitation source (e.g., laser source) and an electrical power source according to the method according to one of Examples 1 to 18 (e.g., by a device according to one of examples 22 to 30), for example, as configured according to example 13, wherein the material flow released by the plasma discharge (e.g., arc discharge) comprises the carbon that is emitted toward the bipolar plate.

Bipolar plates (also referred to as electrode plates) are used, for example, in fuel cells. In a fuel cell, several membrane electrode assemblies may be configured in a stacked configuration. A bipolar plate may be configured between two adjacent membrane electrode assemblies. This may serve to separate the gases between the two adjacent membrane electrode assemblies. A bipolar plate may, for example, have one or more (e.g., meandering) channels (e.g., in the form of trenches) (e.g., in the form of a flow profile) by which the reaction gases oxygen and hydrogen may be supplied to a respective membrane electrode unit. The multiple channels may serve to distribute the reaction gases evenly. Furthermore, the water produced during the reaction may be removed via channels in the bipolar plate (e.g., as water vapor). These channels may, for example, be milled or pressed into both sides of the bipolar plate.

A metallic bipolar plate may be electrically conductive and may therefore serve as an electrically conductive connection between the anode of one adjacent membrane electrode assembly and the cathode of the other adjacent membrane electrode assembly. In order to achieve high electrical conductivity (e.g., above 10⁵ S/m) of the (e.g., metallic) bipolar plates, these may be coated with a carbon layer, as described herein. Such a bipolar plate may be used, for example, for a proton exchange membrane fuel cell (a PEM fuel cell). For example, the metallic bipolar plate may comprise or consist of steel (e.g., of the 316L and/or 304L type) and/or titanium. Alternatively, or additionally, the metallic bipolar plate (e.g., comprising steel) may be or become coated with titanium. A native oxide layer may, for example, be removed prior to coating.

Optionally, the proton exchange membrane of the bipolar plate may be or become coated with a catalyst, such as platinum or palladium. Optionally, the bipolar plate may have a mounting structure (e.g., having one or more through openings) in the edge region thereof, by which the bipolar plate may be mounted.

Example 32 is configured according to Example 31, whereby a carbon layer is formed on the bipolar plate by the material flow.

Example 33 is configured according to Example 31 or 32, wherein the vacuum is provided by a vacuum chamber which, for example, includes two substrate transfer openings through which the bipolar plate is transported and between which a coating area is configured into which the material flow is emitted.

Example 34 is configured according to Example 33, wherein the control and the transport are configured in relation to each other such that a (e.g., dynamic) rate (i.e., material quantity/time) at which the carbon layer is formed on the bipolar plate (also referred to as the coating rate of the carbon layer) is greater than or equal to 50 nm·m/min.

Example 35 is configured according to Example 34, further comprising: performing additional pulse-induced (e.g., laser-induced) plasma evaporation (e.g., arc evaporation) in the vacuum by additionally controlling an additional excitation source (e.g., laser source) and an additional electrical power source according to one of examples 1 to 34, for example, configured according to the method according to claim 13, so that an additional carbon layer is formed between the carbon layer and the bipolar plate; wherein the additional controlling and the transporting are configured in relation to each other such that an additional rate (material quantity/time) at which the additional carbon layer is formed (also referred to as the coating rate of the additional carbon layer) is less than 50 nm·m/min and/or less than the coating rate of the carbon layer.

Example 36 is configured according to one of examples 31 to 35, wherein the bipolar plate is coated with a titanium layer when pulse-induced (e.g., laser-induced) plasma evaporation (e.g., arc evaporation) is performed, wherein the titanium layer is optionally formed in the vacuum, for example by physical vapor deposition (e.g., a sputtering process), before the pulse-induced (e.g., laser-induced) plasma evaporation (e.g., arc evaporation) is performed.

Example 37 is configured according to Example 36, performing a coating process to form the titanium layer on the bipolar plate before performing plasma evaporation (e.g., before forming the carbon layer), e.g., arc evaporation.

Example 38 is configured according to Example 36 or 37, wherein the titanium layer is formed by magnetron sputtering, by plasma evaporation (e.g., arc evaporation), or by high-pulse magnetron sputtering.

Example 39 is configured according to one of examples 36 to 38, wherein the titanium layer includes a layer thickness in a range of approximately 20 nm to approximately 400 nm, preferably in a range of approximately 50 nm to approximately 150 nm.

Example 40 is configured according to one of examples 36 to 39, further comprising: plasma etching a surface of the bipolar plate on which the titanium layer is formed prior to forming the titanium layer.

Example 41 is configured according to one of examples 31 to 40, wherein the bipolar plate includes a surface roughness with a mean arithmetic height less than or equal to 0.3 μm, preferably less than or equal to 0.2 μm, and/or a maximum height less than or equal to 4.0 μm, preferably less than or equal to 2.5 μm.

Example 42 is a bipolar plate with a carbon layer and/or additional carbon layer formed according to the method of one of examples 31 to 41.

Example 43 is configured according to one of examples 1 to 42, wherein the carbon layer (e.g., formed by the material flow) carbon layer and/or additional carbon layer includes a layer thickness in a range of approximately 10 nm to approximately 150 nm, preferably in a range of approximately 20 nm (e.g., 30 nm) to approximately 90 nm.

Example 44 is configured according to one of examples 1 to 43, wherein the carbon layer (e.g., formed by the material flow) and/or additional carbon layer includes a surface contact resistance less than or equal to 10 mΩ·cm², preferably less than or equal to 1 mΩ·cm², and preferably less than or equal to 0.5 mΩ·cm² (e.g., 0.3 mΩ·cm²), and/or greater than 0.1 mΩ·cm².

Example 45 is configured according to one of examples 1 to 44, wherein a carbon content of the carbon layer (e.g., formed by the material flow) and/or additional carbon layer is greater than approximately 90%, preferably greater than approximately 95%, and further preferably greater than approximately 99%.

Example 46 is configured according to one of examples 1 to 45, wherein at least 60%, preferably at least 80%, and further preferably at least 95% of the carbon of the carbon layer (e.g., formed by the material flow) and/or additional carbon layer is sp² hybridized.

Example 47 is configured according to one of examples 1 to 46, wherein the carbon layer (e.g., formed by the material flow) and/or additional carbon layer includes a specific resistance less than or equal to 1 Ω·m, preferably less than or equal to 0.1 Ω·m.

Example 48 is configured according to one of examples 1 to 47, wherein the carbon layer (e.g., formed by the material flow) and/or additional carbon layer includes a contact angle to water greater than or equal to 60°, preferably greater than or equal to 85°, and further preferably greater than or equal to 100°.

Example 49 is configured according to one of examples 1 to 48, wherein the (e.g., formed by the material flow) carbon layer and/or additional carbon layer (e.g., formed by the material flow) includes a refractive index in a range of approximately 2.0 to approximately 3.5, preferably in a range of approximately 2.5 to approximately 3.0, at a wavelength of approximately 0.5 μm.

Example 50 is configured according to one of examples 1 to 49, wherein the carbon layer (e.g., formed by the material flow) and/or additional carbon layer includes a refractive index in a range of approximately 2.0 to approximately 5.0, preferably in a range of approximately 2.5 to approximately 3.5, at a wavelength of approximately 1 μm.

Example 51 is configured according to one of examples 1 to 50, wherein the carbon layer (e.g., formed by the material flow) and/or additional carbon layer includes an average reflectance less than or equal to 0.5 μm, preferably less than or equal to 0.3 μm, at a wavelength of approximately 0.5 μm.

Example 52 is configured according to one of examples 1 to 51, wherein the carbon layer (e.g., formed by the material flow) and/or additional carbon layer includes a nanohardness in a range of approximately 10 GPa to approximately 80 GPa, preferably in a range of approximately 20 GPa to approximately 70 GPa, more preferably in a range from about 30 GPa to about 50 GPa.

Example 53 is one of examples 1 to 52, wherein the excitation source comprises a laser source that is configured to generate a laser pulse (e.g., directed at the target) as an excitation pulse; and/or wherein the plasma discharge comprises an arc discharge; and/or wherein the plasma evaporation comprises arc evaporation.

Example 54 is one of examples 1 to 52, wherein the excitation source comprises an electrical power source that is configured to generate an electrical power pulse (e.g., directed at the target) as an excitation pulse; and/or wherein the plasma discharge comprises a glow discharge; and/or wherein the plasma evaporation comprises sputtering (i.e., atomization by a plasma), e.g., pulse magnetron sputtering, e.g., high-energy pulse magnetron sputtering (HiPIMS). In the context of a glow discharge, for example, a discharge pulse may be provided which comprises the excitation pulse and the first electrical power pulse, which, for example, merge into one another. The excitation pulse may, for example, excite a voltage breakdown which merges into the plasma discharge which is supplied by the first electrical power pulse.

Example 55 A method (e.g., according to one of examples 1 to 54), comprising, controlling an excitation source according to the operating sequence; controlling an electrical power source according to the operating sequence; wherein the operating sequence comprises several phases, in each of which: an excitation pulse 114 directed at a target 112 is generated by the excitation source 110 to excite a plasma discharge at the target 112; a first electrical power pulse 120 is generated by the electrical power source 118 to supply electrical power to the plasma discharge via the target 112; and/or a second electrical power pulse 122 is generated by the electrical power source 118 to accelerate a material flow 116 released from the target 112 by the plasma discharge away from the target (112 and/or toward a substrate holder 104; updating the operating sequence based on a result of the plasma discharge, so that the multiple phases comprise: one or more than one first phase, in each of which the first electrical power pulse 120 and/or the second electrical power pulse 122 are generated per excitation pulse 114, and a second phase, in which: two excitation pulses 114 and/or two first electrical power pulses 120 are generated per second electrical power pulse 122, and/or a first electrical power pulse and a second electrical power pulse are generated, which only partially overlap each other.

Example 56 is one of examples 1 to 55, further comprising: determining (e.g., forming and/or updating) the operating sequence based on a result of the plasma discharge, e.g., based on a result of a coating process performed by the plasma discharge; wherein determining the operating sequence preferably comprises determining (e.g., forming and/or updating) one or more than one first phase, and/or determining (e.g., forming and/or updating) one or more than one second phase. Determining the operating sequence may, for example, comprise determining a ratio (e.g., of the number) of first phases to (e.g., the number) of second phases. Determining the operating sequence may, for example, comprise determining, for each second phase, a ratio (e.g., of the number, duty cycle, and/or power) of the excitation pulse (e.g., of the number, duty cycle, and/or power) to power pulses (e.g., first power pulses and/or second power pulses). Determining the operating sequence may, for example, include determining an overlap (e.g., expressed as overlap time and/or overlap integral) of the first electrical power pulse and the second electrical power pulse. Determining the operating sequence may, for example, comprise determining a state (e.g., power, temporal distribution, e.g., duration and/or start time, amplitude, etc.) of one or more power pulses (e.g., first power pulse and/or second power pulse).

Example 57 is one of examples 1 to 56, wherein the determination of the operating sequence is based on a result of a coating process (e.g., as a result of the plasma discharge) that is performed by the plasma discharge; and/or wherein the determination of the operating sequence is based on a state of a substrate (e.g., as a result of the plasma discharge) that is exposed to the plasma discharge. The state may, for example, be a temperature (e.g., its change) and/or a property (e.g., its change) of the substrate.

Example 58 is one of examples 1 to 57, which is configured in accordance with one of the attached claims (e.g., 1 to 16); and/or is one of the attached claims (e.g., 1 to 16), which is further configured in accordance with one of examples 1 to 57.

### BRIEF DESCRIPTION OF THE DRAWINGS

According to various embodiments,

FIG. 1 shows a vacuum chamber arrangement for coating by laser-induced arc evaporation according to various embodiments in a schematic top view or side view;

FIGS. 2A to 2C show various characteristics relating to the relationship between temperature and rate during coating by laser-induced arc evaporation and the resulting properties.

FIG. 3 shows various pulse shapes of power pulses according to various embodiments.

FIG. 4 shows a vacuum chamber arrangement for coating by laser-induced arc evaporation in a continuous system according to various embodiments in a schematic top view or schematic side view;

FIGS. 5A and 5B, respectively, show an exemplary continuous flow system with multiple coating devices for laser-induced arc evaporation according to various embodiments in a schematic top view;

FIG. 6 shows an operating sequence in a schematic diagram according to various embodiments;

FIGS. 7 and 8, respectively show an operating sequence with schematic timing diagrams according to different embodiments;

FIG. 9A shows an exemplary power pulse according to various embodiments; and,

FIG. 9B shows a diagram according to various embodiments.

### DETAILED DESCRIPTION OF THE INVENTION

The following detailed description refers to the accompanying drawings, which form part of this document and illustrate specific embodiments in which the invention may be practiced. In this regard, directional terminology such as “top,” “bottom,” “front,” “back,” “front,” “rear,” etc. is used with reference to the orientation of the figure(s) described. Since components of embodiments may be positioned in a number of different orientations, the directional terminology is for illustrative purposes only and is in no way limiting. It is understood that other embodiments may be used and structural or logical changes may be made without departing from the scope of the present invention. It is understood that the features of the various exemplary embodiments described herein may be combined with each other, unless specifically stated otherwise. The following detailed description is therefore not to be construed in a limiting sense, and the scope of protection of the present invention is defined by the appended claims.

In this description, the terms “connected,” “connected,” and “coupled” are used to describe both a direct and an indirect connection (e.g., ohmic and/or electrically conductive, e.g., an electrically conductive connection), a direct or indirect connection, and a direct or indirect coupling. In the figures, identical or similar elements are given identical reference symbols, where appropriate.

According to various embodiments, the term “coupled” or “coupling” may be understood in the sense of a (e.g., mechanical, hydrostatic, thermal, and/or electrical), e.g., direct or indirect, connection and/or interaction. For example, several elements may be coupled together along an interaction chain along which the interaction may be exchanged, e.g., a fluid (then also referred to as fluid-conducting coupled). For example, two elements coupled together may exchange an interaction with each other, e.g., a mechanical, hydrostatic, thermal, and/or electrical interaction. A coupling of several vacuum components (e.g., valves, pumps, chambers, etc.) with each other may mean that they are fluidically coupled with each other. According to various embodiments, “coupled” may be understood in the sense of a mechanical (e.g., physical) coupling, e.g., by direct physical contact. A coupling may be configured to transmit mechanical interaction (e.g., force, torque, etc.).

In connection with vacuum components (e.g., a pump, a chamber, a line, a valve, etc.), the term “coupled” or “coupling” may be understood in the sense of a connection to a common vacuum system. The components of the vacuum system may be configured to exchange gas with each other by coupling, whereby the coupling may be gas-separated from the exterior of the vacuum system.

The actual state of an entity (e.g., a device, a system, or a process) may be understood as the entity's factual state or the state that may be detected by sensors. The target state of the entity may be understood as the desired state, i.e., a specification. Control may be understood as an intentional influence on the current state (also referred to as the actual state) of the entity. The current state may be changed in accordance with the specification (also referred to as the target state), e.g., by changing one or more operating parameters (then also referred to as manipulated variable) of the entity, e.g., by a manipulation member. Control may be understood as steering, whereby a change in state due to disturbances is additionally counteracted. To do this, the actual state is compared with the target state, and the entity is influenced, e.g., by a manipulation member, in such a way that the deviation of the actual state from the target state is minimized. In contrast to pure forward-looking sequence control, regulation thus implements a continuous influence of the output variable on the input variable, which is affected by the so-called control loop (also referred to as feedback). In other words, this may be understood to mean that control may be used as an alternative or in addition to steering (or control), or that regulation may take place as an alternative or in addition to steering.

The state of a controllable device (e.g., a structuring device) or a controllable process (e.g., structuring) may be specified as a point (also referred to as an operating point or working point) in a space (also referred to as a state space) that is spanned by the variable parameters of the device or process (also referred to as operating parameters). The state of the device or process is thus a function of the respective value of one or more operating parameters, which thus represent the state of the device or process. The actual state may be determined based on a measurement (e.g., by a measuring element) of one or more operating parameters (then also referred to as sensed variables).

The term “control device” may be understood as any type of logic-implementing entity that may, for example, have a circuit and/or a processor that may execute software stored in a storage medium, in firmware, or in a combination thereof, and may issue instructions based thereon. The control device may, for example, be configured by code segments (e.g., software) to control the operation of a system (e.g., its operating point), e.g., a machine or a plant, e.g., at least its kinematic chain.

Control may be understood as an intentional influence on a system. The current state of the system (also referred to as the actual state) may be changed in accordance with a specification (also referred to as the target state). The parameters of the target state explained here (also referred to as target parameters) may, for example, be implemented by code segments or be stored on a storage medium in some other way. Control may be understood as regulation, whereby a change in the state of the system due to disturbances is additionally counteracted. Illustratively, the control system may have a forward control path and thus illustratively implement a sequence control that converts an input variable (e.g., the specification) into an output variable. However, the control path may also be part of a control loop, so that a control system is implemented. For control purposes, corresponding manipulation members of the system may be controlled, which influence the actual state of the system. Examples of manipulation members include: a drive device (e.g., for providing torque), a valve (e.g., for controlling pressure), a switch (e.g., for closing a discharge path). The drive device may, for example, comprise a linear drive (e.g., a reciprocating piston) or an electric motor.

The term “manipulation member” (e.g., comprising an actuator or actuator) may be understood as a converter that is configured to influence a state, a process (e.g., a coating process), or a device in response to the manipulation member being controlled. The manipulation member may convert a control signal supplied to it (by which the control is carried out) into mechanical movements or changes in physical quantities such as pressure or temperature. An electromechanical (also referred to as an electromotive) manipulation member may, for example, be configured to convert electrical power into mechanical power (e.g., through movement) in response to the control. An electrothermal manipulation member may, for example, be configured to convert electrical power into thermal power in response to the control. An electrothermal manipulation member may, for example, be configured to convert electrical power into thermal power in response to the control signal. An electrical manipulation member may, for example, be configured to convert electrical energy into electrical energy (e.g., of a specific voltage, current, and/or power) in response to the control signal.

A manipulation member may be configured to influence the actual state (also referred to as the operating point) of the process (e.g., its manipulated variable) that is supplied by the manipulation member. The influence may be direct or indirect. The manipulated variable and the sensed variable may, for example, differ from each other. The controlled variable (e.g., pressure) may then be a function of one or more manipulated variables (e.g., voltage).

For example, the manipulation member may change an electrical voltage as the manipulated variable, by which an arc discharge is supplied, so that as a result, a coating rate or a layer thickness is changed as the controlled variable. For example, the manipulation member may change a gas flow rate as the manipulated variable, so that as a result, a pressure is changed as the controlled variable. For example, the manipulation member may change a property of a power pulse (e.g., frequency, total power, pulse shape, pulse duration, etc.), so that as a result, a coating rate or a property of the carbon layer (e.g., layer thickness, electrical conductivity, and/or carbon modification) is changed as a controlled variable. For example, the manipulation member may change a frequency at which an excitation pulse (e.g., laser pulse) is generated, so that as a result, a coating rate or a property of the carbon layer is changed.

Examples of components of a manipulation member include: a power source (if present), a valve (e.g., of a pump arrangement and/or gas supply device), a motor (e.g., of a valve or pump), a circuit (e.g., for controlling the excitation source (e.g., laser source)), or the like. The power source may, for example, be configured to generate one or more voltages (and/or a time dependence thereof), one or more currents (and/or a time dependence thereof), and/or a power (and/or a time dependence thereof) in accordance with the control and to supply them to the coating process. The pump arrangement may, for example, be configured to pump out one or more gases in accordance with the control and thus remove them from the coating process. The gas supply device may, for example, be configured to supply one or more gases to the coating process (also referred to as gas supply) in accordance with the control. The supplied gas may have a gas flow rate (i.e., gas flow per time). The gas flow may, for example, be a standard volume flow supplied to the coating process.

With regard to the control of a manipulation member, reference is made, among other things, to the more easily understandable manipulated variable or its manipulated value, which is influenced by the manipulation member. The above description may be applied analogously to the control variable or its control value, which is supplied to the manipulation member for control, and vice versa. The manipulation member acts as a converter that converts a control signal into the manipulated variable or its manipulated value, so that the manipulated value is a function of the control value. Modern manipulation members are provided, for example, as complex assemblies comprising a manipulation member and a separate control device (also referred to as a manipulation member control device). The manipulation member control device may be configured to receive the setpoint value as input via the control signal and to control the manipulation member in accordance with the setpoint value. The control variable is then generated and transmitted within the manipulation member, so that the manipulated variable is fed to the manipulation member. Less complex manipulation members may only process the control variable as a control signal, so that the control variable is fed to them for control purposes.

More generally, a manipulation member may be controlled by a control signal, whereby the control signal may represent the manipulated variable or its manipulated value and/or the control variable or its control value. Alternatively, or additionally, the control signal may include instructions specifying how the manipulated variable or its manipulated value is to be changed (e.g., its relative change).

A “pulse” relating to a physical quantity (e.g., power, also referred to as a power pulse) may be understood as a temporal change in the quantity such that the value of the quantity (e.g., starting from an initial value, such as zero) increases, exceeds a maximum (also referred to as a peak value), and then decreases again (e.g., to the initial value). The properties of the pulse are a function of the time dependence of the change in the quantity over time. In a pulse, a value of the quantity may change over time from an initial value (e.g., base value) to a peak value (also referred to as the rising edge of the pulse) and then change back from the peak value to the initial value over time (also referred to as the falling edge of the pulse). Examples of the properties of the pulse include: a pulse frequency (specified as a frequency), a pulse start time (e.g., defined by a time delay relative to a reference time), a pulse length (also referred to as pulse duration), the peak value (e.g., an amplitude), the pulse shape, and/or the gradient of the rising edge and/or the falling edge. The temporal duration (also referred to as pulse duration) of the pulse is specified herein in some aspects as an easily understandable width of the time-dependent value curve (e.g., half-width or twice the half-width) of the pulse, but may be specified differently by analogy. The half-value width corresponds to the temporal width of the signal at half the peak value. In some aspects, the pulse duration is specified as a target time duration according to which the pulse is generated by a control device (e.g., by controlling a manipulation member). The pulse shape illustratively describes the geometry of the curve, which describes the magnitude as a function of time, and may be specified as a geometric shape, for example as a rectangle (then also referred to as a rectangular function), sine, triangle, etc. If, for example, the pulse may be described as a rectangular function, the half-width of the rectangular function may be the width of the rectangular function.

If a pulse is generated here, it may be generated according to a target pulse, which illustratively indicates the target state of the pulse to be generated. The target pulse may be specified, for example, as the target time dependence of the pulse to be generated or at least as its properties (e.g., target start time and/or target time delay, target pulse duration, target frequency, target peak value, target pulse shape, and/or target gradient of the rising edge and/or falling edge).

An “electrical power pulse” (abbreviated: power pulse) may be understood as a pulse according to a time-dependent electrical power and may be generated according to a target power pulse. An electrical power pulse may, for example, be implemented by a current pulse if the target power pulse defines a time dependence of the electrical current (e.g., a current peak value, a current gradient, etc.), according to which the power pulse is, for example, controlled and/or regulated (e.g., by using it as a reference variable). Alternatively, or additionally, an electrical power pulse may be implemented by a voltage pulse if the target power pulse defines a time dependence of the electrical voltage (e.g., a voltage peak value, a voltage gradient, etc.), according to which the power pulse is, for example, controlled and/or regulated (e.g., by using this as a reference variable).

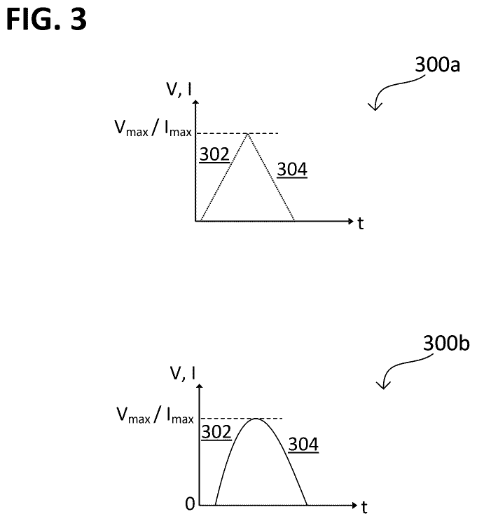

Exemplary electrical power pulses (e.g., as current pulses or as voltage pulses) are shown in FIG. 3. Here, the current or voltage may increase over time, t, from the initial value to the peak value Vmax or Imax along the rising edge 302 and then fall back to the initial value along the falling edge 304. A target power pulse may, for example, have a target pulse shape. This may, for example, be a triangular shape (in 300a) or a sinusoidal shape (in 300b).

Arc evaporation, i.e., evaporation by an arc discharge, belongs to the class of thermal evaporation processes, which have in common that a material to be evaporated (hereinafter also referred to simply as coating material) is heated in such a way that it transitions to its gaseous state (e.g., by absorbing latent heat). Thereby, the melting of the material may (but does not necessarily) occur as an intermediate step. For example, it may evaporate from the melt or sublimate directly. An arc discharge is a form of gas discharge in which the plasma formed is contracted into a tube (or, more vividly, a thin thread, known as an arc). Inside the plasma tube thus formed, high gas temperatures (e.g., in a range from approximately 5,000 Kelvin to approximately 50,000 Kelvin), current intensities (e.g., in a range of approximately 2,000 amperes or more), and gas pressures, by which the coating material is converted into the gaseous phase (also referred to as vaporization). The arc discharge and thus the plasma formation may be of short duration, so that it occurs in pulses. Arc evaporation must be distinguished from the process of cathode sputtering, in which the plasma is generated by a (e.g., continuous or pulsed) glow discharge. In cathode sputtering, instead of thermal evaporation, the material is primarily mechanically atomized by large-area ion bombardment from the plasma, whereby the plasma is provided by continuous glow discharge (e.g., at a voltage of less than 1,000 volts). In cathode sputtering, the pressure is also increased.

An excitation source (e.g., laser source) is a device that is configured to generate an excitation pulse, for example, a radiation pulse, a power pulse (e.g., transmitted as a current pulse or a voltage pulse), or similar. The excitation source is generally configured to excite (e.g., trigger) a plasma discharge (e.g., plasma formation and/or electrical charge transfer by the plasma) by the excitation pulse. For example, an electrical voltage pulse may be used as an excitation pulse to trigger the plasma discharge. A laser source is a device that is configured to generate a laser beam. A laser beam is understood to be a directed (e.g., collinear and/or collimated) propagation of electromagnetic waves, which is, for example, stimulated and/or coherent. The laser source may, for example, comprise an electromagnetic resonator by which the stimulated emission of the laser beam takes place. In contrast to a continuous wave laser, a pulsed laser source generates pulsed laser radiation (also referred to as a laser pulse). The laser pulse may be generated by pulsed excitation or, for example, by a quality switch in the laser itself. Examples of laser sources include gas lasers (e.g., carbon dioxide lasers) and solid-state lasers (e.g., semiconductor lasers).

In uncontrolled arc evaporation (also known as arc vaporization), the location at which the arc discharge occurs is left to chance. However, depending on the material, this may cause local “burn-in” of the cathode, so that the arc discharge is increasingly influenced by its own effects. However, this feedback follows interactions that are difficult to control, resulting in results that are difficult to reproduce.

In particular, in the arc evaporation (also known as ARC evaporation) of carbon, a laser is conventionally used in a modification of arc evaporation to control the ignition of the arc discharge, which locally stimulates the formation of a plasma (also known as laser-induced or laser-assisted arc discharge). In this process, the laser generates a very short pulsed, plasma (to ignite an initial plasma) within the plasma chamber between the anode and the cathode. This initial plasma, lasting from a few 10 ns (nanoseconds) to 100 ns, is then amplified in pulse length and power by an arc discharge using an electrical power source (e.g., pulse power source and/or pulse current source). U_{arc} The plasma formed in this way lowers the impedance between the cathode and anode, so that a voltage applied between the cathode and anode (also referred to as arc voltage) leads to a discharge current through the plasma. In other words, a pulsed arc discharge may be excited by the laser.

First, various aspects are explained below according to different embodiments.

The time course of the electric current pulse (also referred to as the pulse current curve) of such an arc discharge (also referred to as a cathode discharge) at this ignition point may be adjusted by a pulse current source, for example with regard to the pulse shape (e.g., triangle, rectangle, half sine, etc.), the amplitude I_{K} and/or and the pulse length t_{P} of the current pulse.

The laser is guided over the cathode by a mirror system so that the location of the arc discharge may be specifically changed. The laser influences the location of the ignition on the cathode and thus ensures uniform, contact-free ablation of the target material.

For example, the frequency of the location change and/or the pulse frequency of the current pulse may be set using the clock frequency f of the laser.

These parameters may be converted into the so-called source power P_{Q}, for example according to the following relation:

$${P}_{Q} = f {\int }_{0}^{{t}_{P}} {U}_{a r c} {I}_{K} dt$$

The source power serves as a measure of the electrical power converted by the arc discharge to which the substrate is exposed. The source power P_{Q} determined in this way is, as a first approximation, proportional to the coating rate R in nm/min (nanometers per minute).

According to various embodiments, it has been recognized that the arc generated by the laser-induced arc discharge may enable a comparatively high coating rate R(P_{Q}) (i.e., an amount of material vaporized per time). In a continuous flow system, the coating rate (rate at which the transported substrate is coated) and/or the layer thickness are often normalized to the transport speed v of the substrate, which is then referred to, for example, as the dynamic deposition rate (e.g., in nm·m/min).

In a continuous system, the rate at which the transported substrate is coated (also referred to as the coating rate) is often specified as the dynamic deposition rate (e.g., in nm·m/min), which is a function of the product of the layer thickness produced by coating and the transport speed at which the substrate is transported, which provides more comparable values for the deposition rate for different scenarios.

The dynamic coating rate illustratively indicates, for a rate R(P_{Q}), the resulting coated length l of the substrate per time t (e.g., in minutes), whereby l may be expressed, for example, according to the following relation: l=v·t (e.g., in minutes). The ddr is thus a function of the transport speed v at which the substrate is transported past the coating source.

In a (e.g., inline) continuous flow system, a substrate (such as the bipolar plate) may be transported past the cathode of the coating source along a transport path by a transport device, so that the material vaporized by the arc discharge (also referred to as the material flow) hits the substrate and thus the material layer, such as the carbon layer (e.g., according to one or more specifications, such as a target layer thickness), is formed.

Examples of parameters for which specifications exist include: the layer thickness (also referred to as the target layer thickness), the properties of the coating (also referred to as the target layer properties), and/or the throughput (also referred to as productivity), which may be expressed, for example, as the length of the substrate that is coated per unit of time and/or in relation to the entire system (then also referred to as plant throughput).

This is because the layer thickness is a function of the coating rate and the transport speed, and thus also a function of the source power.

The coating of the substrate (also referred to as the deposition of a layer on the substrate) in accordance with one or more specifications (e.g., a target layer thickness and/or a target transport speed) may be carried out using the source power as a manipulated variable. For example, as a first approximation, the source power is proportional to the target transport speed, provided that the target layer thickness is invariant, which allows the plant throughput to be scaled. However, the energy input into the substrate (e.g., normalized to the area of the substrate) is a function of the target layer thickness and thus of the dynamic rate ddr.

According to various embodiments, it is addressed that the substrate is heated by the energy input of the coating plasma, and its temperature may rise comparatively sharply. The properties of some substrates (e.g., their materials and/or coatings) may deteriorate above (at least) a critical material temperature. An analysis of the calorimetric properties of the substrate (e.g., the substrate material), which is explained below by way of example, provides insight into this context, in particular for assessing the feasibility of the coating process using laser-induced arc evaporation on an industrial scale.

For example, the heat capacity C of a substrate, such as a stainless steel foil (e.g., for the production of a bipolar plate), decreases the thinner the substrate is, and may be in the range of 1 to 10 mJ/K (millijoules per Kelvin), e.g., normalized to one square centimeter of the substrate (then also referred to as surface heat capacity) that is exposed to the plasma (e.g., in millijoules per square centimeter and per Kelvin). The surface heat capacity of a metallic foil with a thickness t_{D} made of a material (such as stainless steel or titanium) with a density ρ and a specific heat capacity c is given by C=cρt_{D}. The energy input E (e.g., in J/cm²) of a coating source leads to a temperature increase of the substrate by ΔT=E/C. At the same time, the substrate may release some of the heat (e.g., via radiation or heat conduction), which inhibits the temperature increase of the substrate, but in a vacuum this contribution is so small that it may be neglected in the dynamics of the coating and, at least on the short time scale of the energy input, as a first approximation.

In an industrial plant, processes that extract thermal energy from the substrate (e.g., in comparison to a laboratory plant) may be difficult to implement. Furthermore, industrial plants often have higher requirements (e.g., in comparison to a laboratory plant) in terms of robustness against disturbance variables.

In this context, it has been recognized that one example of this is carbon layers that may be formed on a substrate (e.g., a bipolar plate). Such carbon layers may be subject to high requirements, for example with regard to their properties (also referred to as layer properties), such as surface contact resistance, corrosion resistance, adhesion, etc., in order to ensure high quality.

These properties (e.g., quality) may also be influenced by a voltage applied to the substrate (also referred to as substrate bias voltage (U_{B})), which accelerates the ions in the plasma in addition to their initial energy. High-energy ions may influence the layer morphology, for example, but they also increase the energy input into the substrate. Depending on the plasma transmission in the coating chamber, a proportion η of the arc current integral generated on the cathode is fed to the substrate as ion current with a flight time-related time delay. The additional power input P_{B} (also referred to as bias power) resulting as a function of the substrate bias voltage (U_{B}) may be expressed in a first approximation by the following relation:

$${P}_{B} = {U}_{B} η f {\int }_{0}^{{t}_{P}} {I}_{K} dt$$

If there is a minimum energy for the high-energy ions to promote the formation of a target layer morphology, this may result in a lower limit for the substrate bias voltage, for example in the range of 800V or greater.

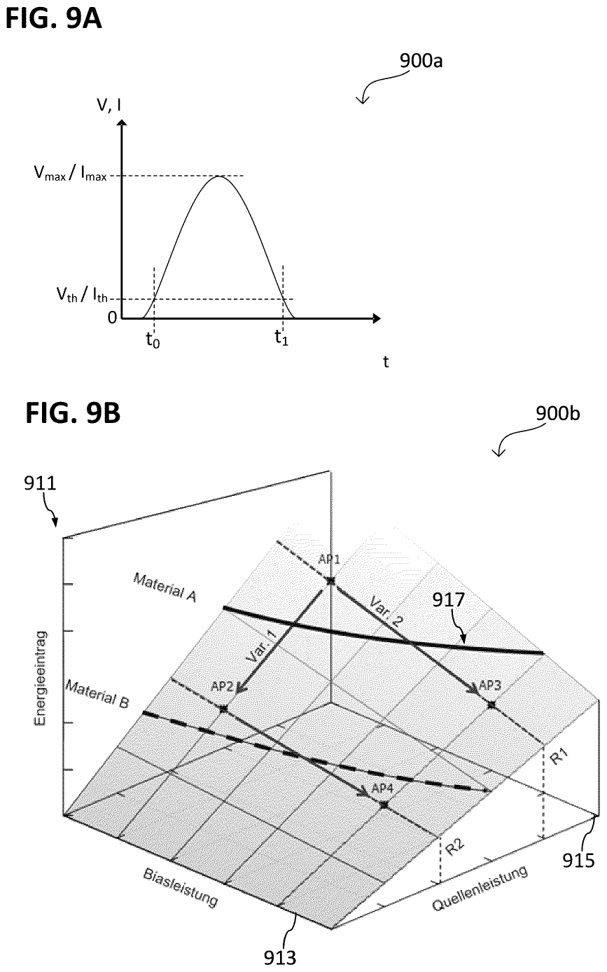

The energy input into a substrate that is transported past the plasma at an (e.g., invariant) actual transport velocity may thus be understood as a function of two power sources (P_{Q} and P_{B}), which depend on the operating point of the plasma source and the substrate. This relationship is illustrated in Diagram 900b (see FIG. 9B), in which the energy density 911 input into the substrate is plotted schematically (a.u.) against the bias power 913 and the source power 915.

Based on a maximum temperature Tₘₐₓ as a specification, which the substrate should not exceed during coating, the maximum energy input Eₘₐₓ may be determined as a specification, for example, which is introduced into the substrate during coating, for example, according to the following relation: Eₘₐₓ=(Tₘₐₓ−T₀)C. Optionally, upstream processes to which the substrate is exposed, and which influence the starting temperature T₀ of the substrate may also be taken into account.

In an exemplary implementation, the maximum temperature (as the critical material temperature) may be approximately 600° C., above which (e.g., formed by laser-induced arc evaporation) tend to grow in a morphology that deviates more strongly from the target (e.g., a substantially amorphous carbon modification or a substantially crystalline carbon modification without crystallographic texture), and thus no longer meet the property requirements.

According to various embodiments, it has been recognized that, in addition to the parameters described above, there are additional manipulated variables (see embodiments) that may be used to influence (e.g., reduce) the energy input (and the resulting power input) into the substrate, while at the same time enabling the production of a high-quality carbon layer. This is based, among other things, on the realization that only a portion of the high-energy ions is sufficient to promote the formation of the desired layer properties.

In an exemplary implementation, the source of the substrate bias voltage (also referred to as the bias pulse current source) is provided (e.g., controlled) in such a way that only a portion of the ionized plasma is post-accelerated by the substrate bias voltage, which reduces the energy input into the substrate. For this purpose, pulse overlap and/or pulse omission is implemented according to various embodiments. For example, the period of time during which the substrate bias voltage is applied to the substrate may be provided in such a way that only a proportion PO (in %) of the substrate power pulse is effective. For example, it has been recognized that the value of PO may be reduced to 25% without significantly affecting the layer properties.

In an exemplary implementation, the operating point (AP, of which AP1, AP2, AP3, AP4 are shown, for example) may be determined as follows (see FIG. 9). In accordance with one or more specifications, a target (also referred to as a target rate) R=R1 may be determined for the coating rate R, for example based on a specification for the layer thickness and/or the system throughput. In the example for material A, R=R1 results in an energy input at operating point AP1 that exceeds the maximum energy input as threshold value 917 (black line). Based on this, the target rate could be reduced to R=R2<R1 (see Var. 1) and a possible operating point AP2 could be reduced at the expense of the layer thickness. In the case of the example of forming a carbon layer, a critical material temperature as threshold value 917 may limit the dynamic coating rate (e.g., per cathode) to less than 50 nm·m/min, for example. At a fixed transport speed, the scope for selecting the operating point (also referred to as the selection range) is increased by the manipulated variable of the bias power 913. Traditionally, the bias power was invariably specified due to the existing boundary conditions. In contrast, according to various embodiments, the bias power 913 is available as a manipulated variable that may be varied alternatively or in addition to the manipulated variables of the source power and the transport speed.

Alternatively, or in addition, various embodiments allow the energy input to be reduced to the operating point AP3 by pulse overlapping and/or pulse omission (see Var. 2) without necessarily having to change the target rate. For example, in the case of a thermally even more sensitive material B, both the target rate may be reduced to R=R2<R1 (which results in a lower layer thickness) and the pulse overlap and/or pulse omission may be changed to promote coating of the substrate at operating point AP4 in accordance with the coating quality requirements. If, for example, R2 represents the value at which the minimum layer thickness is generated on the substrate, an AP (see AP4) that is not conventionally accessible is opened up for material B.

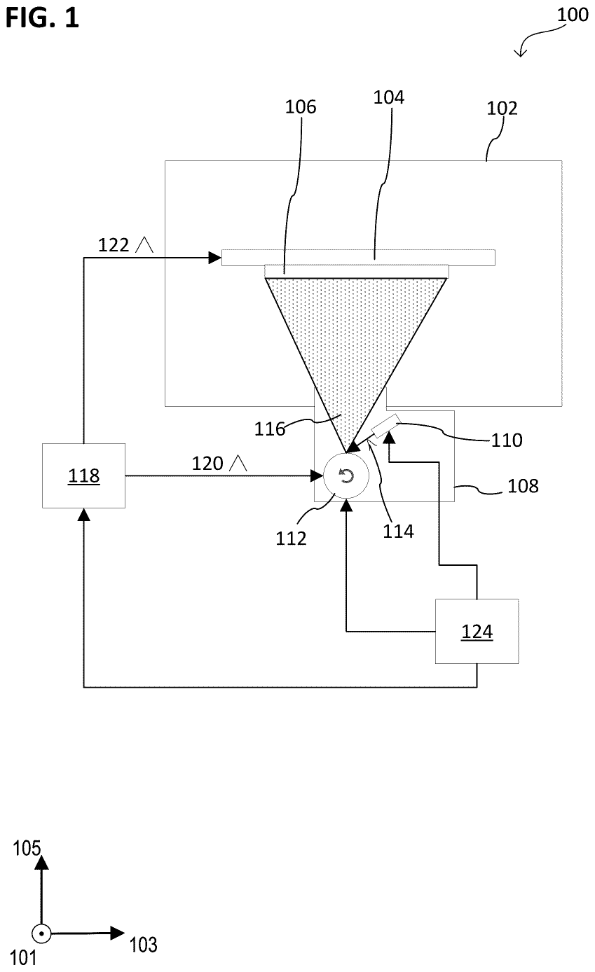

FIG. 1 illustrates a vacuum chamber arrangement 100 for coating by laser-induced arc evaporation according to various embodiments in a schematic top view (or a schematic side view). Pulsed signals are indicated by a circumflex “\hat{ }”.

The vacuum arrangement 100 may comprise a vacuum chamber 102. A vacuum chamber 102 may, for example, be provided by a chamber housing in which one or more vacuum chambers may be provided. The chamber housing may, for example, be coupled to a pump arrangement, e.g., a vacuum pump arrangement, for providing a negative pressure or a vacuum (vacuum chamber housing) and may be configured to be stable in such a way that it may withstand the effects of air pressure in the pumped-down state. The pump arrangement (comprising at least one vacuum pump, e.g., a high-vacuum pump, e.g., a turbomolecular pump) may enable part of the gas to be pumped out of the interior of the vacuum chamber 102. The vacuum chamber 102 may optionally have a chamber cover which seals the interior of the vacuum chamber 102 in a vacuum-tight manner. The plasma of the arc discharge may accordingly have a negative pressure (e.g., a vacuum).

The chamber housing, e.g., a vacuum chamber 102 provided therein, may be configured such that a negative pressure (i.e., a pressure less than atmospheric pressure) may be provided therein, e.g., a vacuum (i.e., a pressure of less than 0.3 bar), e.g., a pressure in a range from approximately 10 mbar to approximately 1 mbar (in other words, rough vacuum) or less, e.g., a pressure in a range from approximately 1 mbar to approximately 10⁻³ mbar (in other words, fine vacuum) or less, e.g., a pressure in a range from approximately 10⁻³ mbar to approximately 10⁻⁷ mbar (in other words, high vacuum) or less, e.g., a pressure less than high vacuum, e.g., less than approximately 10⁻⁷ mbar. Atmospheric pressure (e.g., 1 bar) may be the pressure acting on the chamber housing from the outside.

The vacuum assembly 100 may include a coating device 108. The coating device 108 may be configured to coat using a laser-induced arc discharge.

The gas pressure (also referred to as operating pressure) used to operate the coating device 108 and/or the gas or gas mixture (also referred to as operating gas) supplied to the coating device 108 may be highly dependent on the application. For example, the operating pressure may be in a range from approximately 10⁻⁴ mbar (millibar) to approximately 5·10⁻⁴ mbar. For example, the operating gas may comprise one or more of the following gases: oxygen (e.g., molecular oxygen, i.e., O₂, nitrogen (e.g., molecular nitrogen, i.e., N₂), hydrogen (e.g., molecular hydrogen, i.e., H₂), one or more than one hydrocarbon compound, or a gas mixture thereof. The operating gas may comprise the working gas (e.g., an inert gas) and/or a reactive gas. The reactive gas may comprise, for example, hydrogen.

The coating apparatus 108 may include a target holder (not shown) for holding a target 112. The target holder may provide a rotational axis and may be configured to cause the target 112 (when held in the target holder) to rotate about the rotational axis.

The coating apparatus 108 may include a laser source 110. The laser source 110 may be configured to generate a laser pulse 114 (i.e., pulsed laser beam) toward the target holder (e.g., toward the target 112 held in the target holder).

During operation of the vacuum assembly 100, the target 112 may be held in the target holder. The laser source 110 may be configured to generate the laser pulse 114 directed at the target 112. This laser pulse 114 may excite (e.g., induce) an arc discharge at the target 112. The target 112 may be operated as a cathode in this case. Therefore, the target holder may also be referred to as a cathode end block.

A cathode end block (hereinafter also referred to as an end block for simplicity) may be defined as a device that is configured to hold and supply a cathode, e.g., with torque for rotating the cathode, with electrical energy, and optionally with a cooling fluid. To provide the torque, the end block may have a drive device (e.g., a motor) or at least be coupled to such a device. The end block may be mounted inside a vacuum chamber, e.g., on a through-opening in the chamber wall (also referred to as a supply opening). The electrical energy and/or the cooling fluid (and optionally the torque) may be supplied to the end block through the supply opening. Optionally, one or more additional media may be supplied to the end block, which serve to supply the cathode, e.g., data for controlling and/or reading out a sensor.

The target 112 may generally have or consist of a coating material that is to be converted into a gaseous state.

The target 112 may generally be tubular (a so-called tube cathode). The target 112 may, for example, have a tubular carrier (a so-called carrier tube) on which a (e.g., brittle and/or fragile) coating material may be attached. For example, the target 112 may have a carrier tube by which the coating material is carried. For clarity, the coating material may surround the target base tube in the form of a jacket. Alternatively, target 112 may have a tubular coating material (a so-called target tube) (e.g., a tube made of coating material) or be formed therefrom. The diameter of the tubular target may, for example, be in a range from approximately 10 cm (centimeters) to approximately 50 cm, e.g., approximately 20 cm or more.

The vacuum assembly 100 may comprise an electrical power source 118 (also referred to as an electrical power supply). The electrical power source 118 may be configured to provide an operating voltage (e.g., a direct voltage), e.g., pulsed. For this purpose, the electrical power source 118 may, for example, comprise or be formed from a pulse current source.

The operating voltage may be applied between an anode and the target holder. The operating voltage to be applied may be set in such a way that an electric current may discharge between the anode and the cathode, but no spontaneous ignition (uncontrolled start of the discharge) occurs. For this purpose, the operating voltage may be lower than the ignition voltage (i.e., the voltage at which an arc discharge is ignited) and higher than a burning voltage (i.e., the voltage at which an arc discharge occurs). For example, an anode potential at the anode may be in a range of approximately 10 to approximately 20 V. A cathode potential at the cathode may, for example, be negative (e.g., with respect to electrical ground) and/or its magnitude may be in a range from about 240 V to about 350 V.

The electrical power source 118 may be configured to generate a first electrical power pulse 120. The first electrical power pulse 120 may be applied to the target 112. The first electrical power pulse 120 may be configured to electrically supply the arc discharge (induced by the laser pulse 114) (e.g., by the target 112). For this purpose, the target holder may be electrically coupled to the electrical power source 118.

The vacuum arrangement 100 may comprise a control device 124. The control device 124 may be configured to control the laser source 110. For example, the control device 124 may control the laser source 110 to generate the laser pulse 114 and thus initiate a laser-induced arc discharge. The control device 124 may be configured to control the electrical power source 118. For example, the control device 124 may control the electrical power source 118 to generate the first electrical power pulse 120. In this case, the control device 124 may control the electrical power source 118 to generate the first electrical power pulse 120 in accordance with a (first) target power pulse (e.g., a target current pulse). The first electrical power pulse 120 may be conveyed by a current pulse generated (or controlled) by the electrical power source 118.

The electrical power source 118 may have an output filter which is configured to be controlled in response to a target power pulse in order to influence a time dependence of the electrical power pulse.

The (first) target power pulse (e.g., target current pulse) may define a time dependence of the electrical power (e.g., the electrical current). According to various aspects, the (first) target power pulse may be a target current pulse according to a target time dependence with a gradient in a range of approximately 10·10⁶ A/s to approximately 24·10⁶ A/s (see, for example, the rising and falling edges 302, 304 shown in FIG. 3).

Successive pulses may be generated with a time offset between them, e.g., according to a target frequency. The frequency may also be referred to as the pulse frequency. The target pulse frequency of the (first) target power pulse may be as specified in Example 9, for example.

If reference is made herein to a target parameter (e.g., a target power pulse, a target time delay, and/or a target frequency, etc.), this may be implemented by code segments which may be stored, for example, in a data memory associated with the control device 124. The code segments may be stored in the data storage device in a suitable manner, for example as a list (e.g., table), series of values, algorithm, etc. A data storage device (also referred to generally as a storage medium) may be, for example, a non-transitory data storage device. The data storage device may, for example, comprise or be formed from a hard disk and/or at least one semiconductor memory (such as read-only memory, direct access memory, and/or flash memory). The read-only memory may, for example, be an erasable programmable read-only memory (also referred to as EPROM). The random-access memory may be a non-volatile random-access memory (also referred to as NVRAM).

Control performed by the control device 124 may be carried out according to an operating sequence. This operating sequence may be stored in the data memory in a suitable manner, for example as an algorithm or in another way by code segments.

The target holder may be configured to stimulate a rotational movement of the target 112 around a rotational axis. For example, the target holder may have a drive (e.g., an electric motor) for this purpose, which is configured to apply torque to the target. The control device 124 may be configured to control the drive of the target holder in order to control the rotational movement (e.g., rotational frequency). The rotational frequency may be as specified in Example 25, for example.

By the electric arc, the (e.g., solid) target material may be converted at least partially (e.g., at the discharge point on the target 112) into the gaseous state of aggregation (also referred to simply as the gaseous state or as vapor). The conversion may also be referred to simply as vaporization, but may generally also involve sublimation (i.e., a direct transition from the solid state of the target material to the gaseous state). The material released from the target 112 by the arc discharge (e.g., vaporized from the target 112) may form a material flow 116 away from the target 112.

During operation of the vacuum assembly 100, one (or more than one) substrate 106 may be coated by the material flow 116. For this purpose, the vacuum assembly 100 may have a substrate holder 104 that is configured to hold one or more substrates. The substrate holder 104 may be located in vacuum chamber 102. In various embodiments, a distance between the axis of rotation and the substrate holder may be in a range of approximately 410 mm to approximately 750 mm.

The or each substrate may generally comprise a workpiece, e.g., a semi-finished product (e.g., a rod, a sleeve, or a plate) or a component of a more complex device. Examples of a substrate include: a piston ring, a bearing component, a tool, a chain, a drive chain, an obtuse-angled geometry; a knife, or a component sensitive to sliding friction. Each substrate may, for example, be cylindrical, plate-shaped, or have another shape.

The or each substrate may comprise or be formed from at least one of the following: a ceramic, a glass, a semiconductor (e.g., amorphous, polycrystalline, or single-crystal semiconductor, such as silicon), a metal, and/or a polymer (e.g., plastic). The ceramic may, for example, comprise an oxide, a nitride, and/or a carbide of a metal.

Within the scope of this description, a metal (also referred to as a metallic material) may comprise (or be formed from) at least one metallic element (i.e., one or more metallic elements), e.g., at least one element from the following group of elements: copper (Cu), iron (Fe), titanium (Ti), nickel (Ni), silver (Ag), chromium (Cr), platinum (Pt), gold (Au), magnesium (Mg), aluminum (Al), zirconium (Zr), tantalum (Ta), molybdenum (Mo), tungsten (W), vanadium (V), barium (Ba), hafnium (Hf), samarium (Sm), silver (Ag), and/or lithium (Li). For example, a metal may comprise or be formed from a metallic compound (e.g., an intermetallic compound or an alloy) or a compound of at least one metallic element (e.g., from the group of elements) and at least one non-metallic element (e.g., carbon), such as steel.

In a clear example, the substrate 104 may be a (e.g., metallic) bipolar plate and the target 112 may comprise or consist of carbon, so that a carbon layer may be formed on the bipolar plate by the material flow 116 generated by the laser-induced arc discharge. The carbon layer may, for example, comprise or be formed from tetrahedral amorphous carbon, in which hydrogen is optionally stored. However, the carbon may also be present in another carbon modification.

Carbon of the carbon layer may, for example, be present in one of the following carbon modifications: graphite; amorphous carbon; tetrahedral carbon; diamond-like carbon; fullerenes; diamond; carbon nanotubes; amorphous tetrahedral carbon; and/or nanocrystalline carbon, e.g., nanocrystalline graphite. Optionally, hydrogen may be incorporated into the carbon (i.e., a hydrogen-doped carbon configuration).

According to various aspects, the electrical power source 118 may be configured to generate a second electrical power pulse 122. The second electrical power pulse 122 may be configured to accelerate the (e.g., ionized portion of the) material stream 116 away from the target 112 and toward the substrate holder 104. For this purpose, the substrate holder 104 may be electrically coupled to the electrical power source 118. The second electrical power pulse 122 may increase the kinetic energy with which the material of the material stream 116 strikes the substrate 106. This may, for example, result in the formation of a more compact layer. In some applications, this second electrical power pulse 122 may even promote the achievement of desired properties (e.g., a minimum surface contact resistance or a minimum corrosion resistance in the case of a carbon-coated bipolar plate). The control device 124 may control the electrical power source 118 to generate the second electrical power pulse 122 in accordance with a second target power pulse (e.g., a target voltage pulse). The second electrical power pulse 122 may be conveyed by a voltage pulse generated (or controlled) by the electrical power source 118.

A pulse maximum current of the arc discharge may be or become limited (e.g., by the operating sequence), for example to a pulse maximum current in a range from approximately 1000 A to approximately 5000 A, preferably in a range from approximately 1600 A to approximately 3000 A, and further preferably in a range of approximately 2000 A to approximately 2500 A.

According to various aspects, the laser pulse 114, the first electrical power pulse 120, and optionally also the second electrical power pulse 122 may be coordinated, i.e., synchronized (e.g., by the operating sequence), e.g., in such a way that they overlap in time. For this purpose, the control device 124 may, for example, have a clock generator by which the laser pulse 114, the first electrical power pulse 120 and, optionally, the second electrical power pulse 122 are synchronized with each other. Each clock pulse of the clock generator may define a reference time point, e.g., exactly one reference time point per phase and/or at which the phase begins. For clarity, the reference point in time may be the start of the phase. Optionally, there may be a time offset (e.g., in the us range) between the laser pulse 114 and the first electrical power pulse 120 and/or between the laser pulse 114 and the first electrical power pulse 120 and/or between the first electrical power pulse 120 and the second electrical power pulse 122, etc. There may be a time offset (e.g., in the us range), which may take into account, for example, the duration between the generation of the laser pulse 114 and its impact on the target 112 and/or the duration between the generation of the material flow 116 and its impact on the substrate 106. For example, the second electrical power pulse 122 (if it is generated in a clock cycle and/or phase) may be generated with a (second) target time difference (also referred to as a target time delay) from the reference point in time (e.g., the start of the respective phase). Illustratively, the second electrical power pulse 122 may begin temporally after the first electrical power pulse 120 (if this is generated without a target time delay or with a smaller target time delay than the second electrical power pulse 122).

According to various aspects, the substrate 106 may be coated by iteratively (according to a target frequency) generating a respective arc discharge with an associated material flow 116. Iteration herein means the repeated excitation of the arc discharge by one or more pulses, for example by the laser pulse 114 and by the first electrical power pulse 120. Per iteration, the laser pulse 114, the first electrical power pulse 120, and optionally the second electrical power pulse 122 may be generated.

For example, the operating sequence may have one or more phases of a first type, in which the laser pulse 114, the first electrical power pulse 120, and the second electrical power pulse 122 are generated per iteration. For example, the operating sequence may have one or more phases of a second type (which, for example, includes twice the duration of the first phase), in which two (or more than two) iterations take place, in each iteration of which the laser pulse 114 and the first electrical power pulse 120 are generated, but only in one of the two (or more than two) iterations is the second electrical power pulse 122 generated. For example, the operating sequence may include at least one phase in which the laser pulse 114, the first electrical power pulse 120, and the second electrical power pulse 122 are generated, with the first electrical power pulse 120 and the second electrical power pulse 122 only partially overlapping (in time).

Although a single electrical power source 118 is described herein, it is understood that the vacuum assembly 100 may also include multiple electrical power sources, each of which may generate a power pulse described herein, for example, a first power source may generate the first power pulse and a second power source may generate the second power pulse.

Optionally, the vacuum assembly 100 may include a particle filter disposed between the target holder and the substrate holder 104 and configured to filter the material stream 116 released from the target 112 by the arc discharge. Filtering a material stream may be understood as separating the material stream into a first part and a second part, wherein the first part is fed to the substrate 106 and the second part is not. For example, the second part of the material stream may be collected before it reaches the substrate 106.

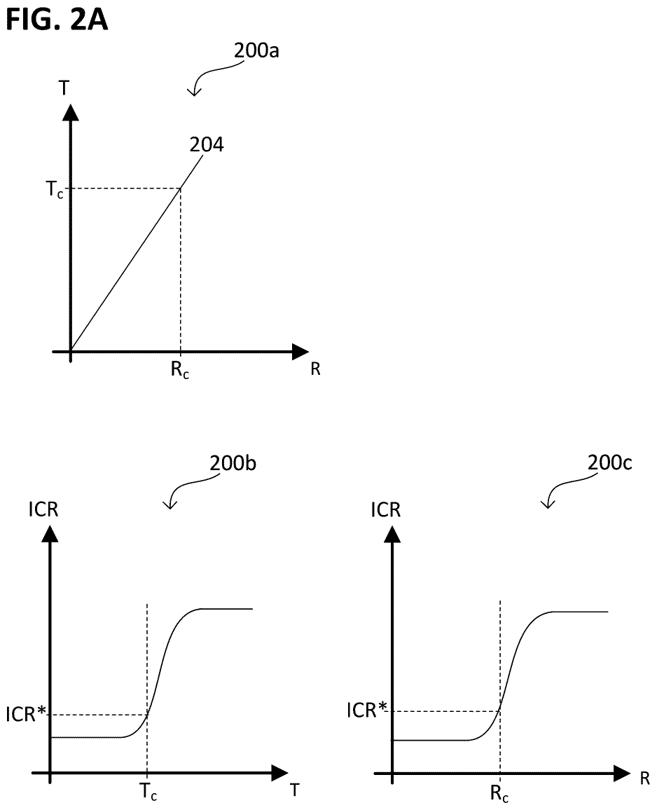

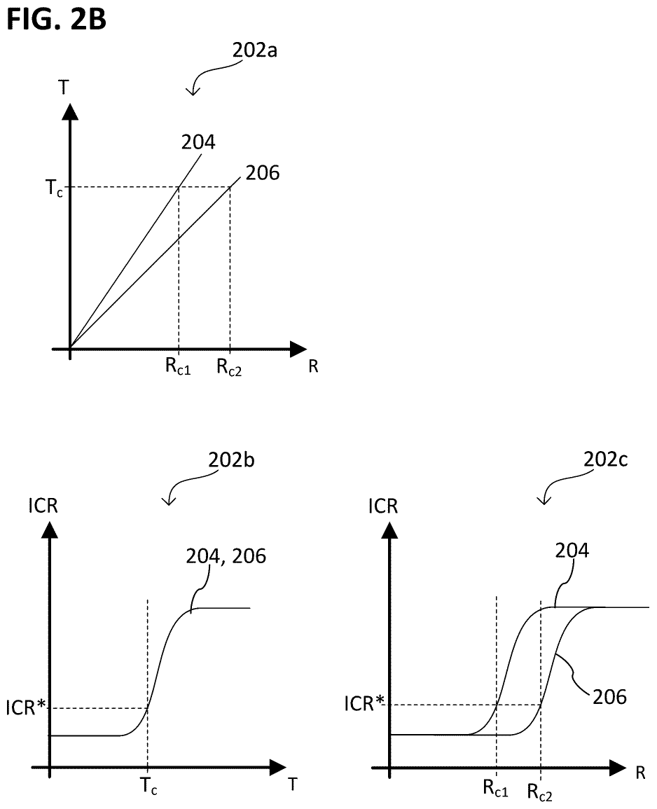

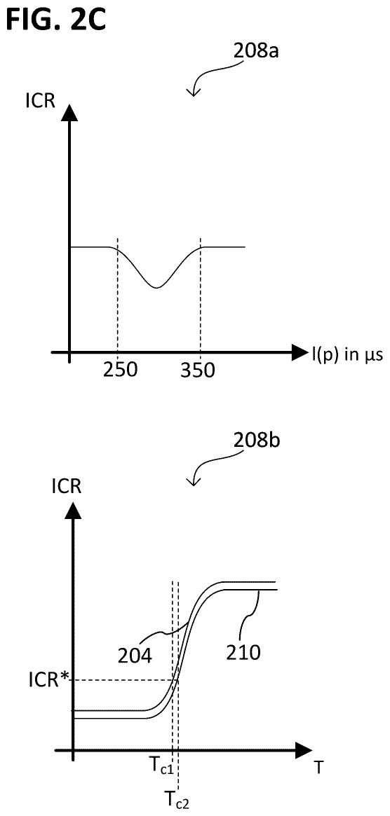

FIG. 2A to FIG. 2C each shows different characteristics of coating by laser-induced arc evaporation with regard to the relationship between temperature and rate and its influence on the surface contact resistance, ICR, of the layer produced accordingly, which is shown schematically.

The term “surface contact resistance” may refer to the contribution of the surface to the total resistance of a system, which may be attributed to the contact areas of electrical conductors and connections as opposed to the intrinsic resistance.

It is understood that surface contact resistance is an exemplary material property and is used here for illustrative purposes. Accordingly, it is understood that the principles described herein may also apply analogously to other properties.

As illustrated by the rate-temperature curve 204 in diagram 200a of FIG. 2A, a higher (e.g., dynamic) coating rate, R, results in a higher material temperature of the layer due to the energy input into the formed layer. Diagrams 200b and 200c show that the surface contact resistance, ICR, may increase with increasing temperature or rate.

For example, if a layer is to be produced that includes a surface contact resistance less than or equal to a target contact resistance, ICR*, this limits the temperature that the material may reach during coating to a critical temperature, T_{c}. Since the temperature depends on the coating rate, the coating rate is also limited to a critical coating rate, R_{(c)}. The critical temperature, T_{(c)}, may be accompanied by a critical change in the properties of the layer (e.g., due to delamination of the layer).

The second electrical power pulse 122 described herein (e.g., as a voltage pulse, then also referred to as a bias voltage pulse) may promote the surface contact resistance reaching or falling below the target contact resistance, ICR*, (and/or other desired properties, such as a desired corrosion resistance). For example, in the case of carbon coating, the use of the second electrical power pulse 122 may lead to a stalk-like structure of the carbon or at least promote its formation, which may improve properties such as the target contact resistance, ICR*, and/or corrosion resistance. For example, as the peak value of the second electrical power pulse 122 increases, the sp²-hybridized portion of carbon bonds may be increased. For example, a stalk-like structure may be produced starting at a peak value of approximately 700 V. In this case, the stalk diameter may be less than or equal to 50 nm, preferably less than or equal to 25 nm.

The diagrams 200a, 200b, 200c shown in FIG. 2A refer to a respective progression in the case that the second electrical power pulse 122 is generated per generation of the arc discharge (i.e., in each iteration).

It has been recognized that if this second electrical power pulse 122 is omitted in some iterations of generating the arc discharge, the temperature, T, of the layer may be reduced without significantly affecting the contact resistance, so that, for example, the target contact resistance, ICR*, may still be undershot at the same time. In this case, phases may occur in which several arc discharges are excited per second electrical power pulse 122.

Diagram 202a in FIG. 2B shows a schematic rate-temperature curve 206 for the case in which the second electrical power pulse 122 is omitted in some iterations. Diagrams 202a, 202b, and 202c show that, at the same critical temperature, T_{c}, the critical rate of R_{c1} in the case of the rate-temperature curve 204 increases to R_{c2} in the case of the rate-temperature curve 206. Consequently, this allows the use of higher (e.g., dynamic) coating rates. According to various aspects, omitting the second electrical power pulse 122 from every tenth iteration already allows a dynamic coating rate of significantly greater than or equal to 50 nm/min or m/min. By omitting the second electrical power pulse 122 from every fifth iteration, a dynamic coating rate greater than or equal to 300 nm·m/min may be achieved in the case of coating the bipolar plate with carbon, for example.

The control device 124 may be configured to implement the omission of a second electrical power pulse 122, e.g., to control it, e.g., by the operating sequence. For this purpose, the control device 124 may, for example, have a counter which counts the first and/or second power pulse and/or the generation of the laser pulse. However, omitting too many second electrical power pulses 122 may result in certain target properties no longer being achieved. Therefore, the omission of the second electrical power pulse 122 may be limited to at most every nth iteration, where n may be any natural number greater than or equal to two (e.g., three or more, e.g., four or more, e.g., five or more). This may depend on the desired properties of the layer to be produced, the material, etc. For example, in the case of coating the bipolar plate with carbon, the omission of the second electrical power pulse 122 may be limited to at most every fifth iteration, so that the target contact resistance, ICR*, is still achieved. For example, the operating sequence may have one phase of the second type for every several (e.g., two or three or four) phases of the first type.

A coating process may have several phases, each of which may have one or more iterations of generating the arc discharge. If the second electrical power pulse 122 is not omitted in the one or more iterations of a first phase, then in this first phase, exactly one first electrical power pulse 120 and exactly one second electrical power pulse 122 are generated per laser pulse. If the second electrical power pulse 122 is omitted in one of two iterations of a second phase, then in these two iterations of the second phase, two laser pulses 114 and two first electrical power pulses 120 are generated per second electrical power pulse 122.

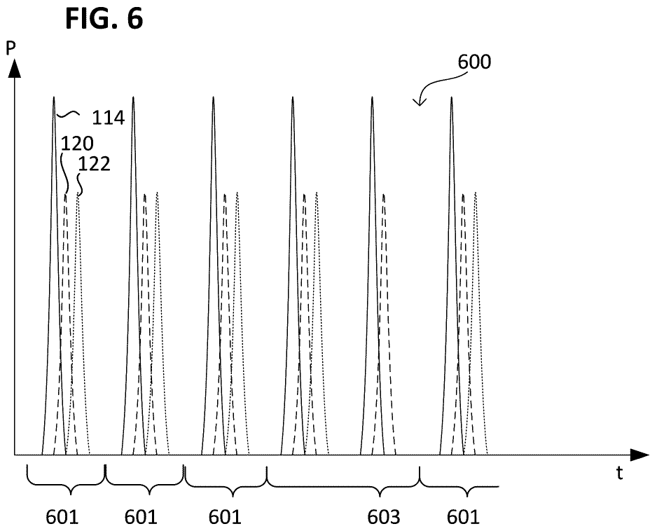

An exemplary operating sequence 600 in this regard is shown in FIG. 6.

It has also been recognized that the temperature, T, of the layer may be reduced additionally or alternatively if the second electrical power pulse 122 and the first electrical power pulse 120 (when these are generated in one phase and/or one clock cycle) only partially overlap in time. This temporal overlap may also be referred to as pulse coverage. If a first pulse and a second pulse start at the same time (e.g., the reference time of a clock cycle) and the first pulse and the second pulse end at the same time (e.g., because they have the same target pulse duration), there is complete temporal overlap. In this case, the pulse overlap is equal to 1 (i.e., 100%). If one pulse begins after another pulse (e.g., due to a target time delay with respect to the reference time of a clock) and/or if one pulse ends before another pulse (e.g., due to different target pulse durations), these pulses only partially overlap. In this case, the pulse coverage is less than 1 (i.e., less than 100%).

For clarity, the temperature, T, of the layer may additionally or alternatively be reduced by reducing the pulse overlap.

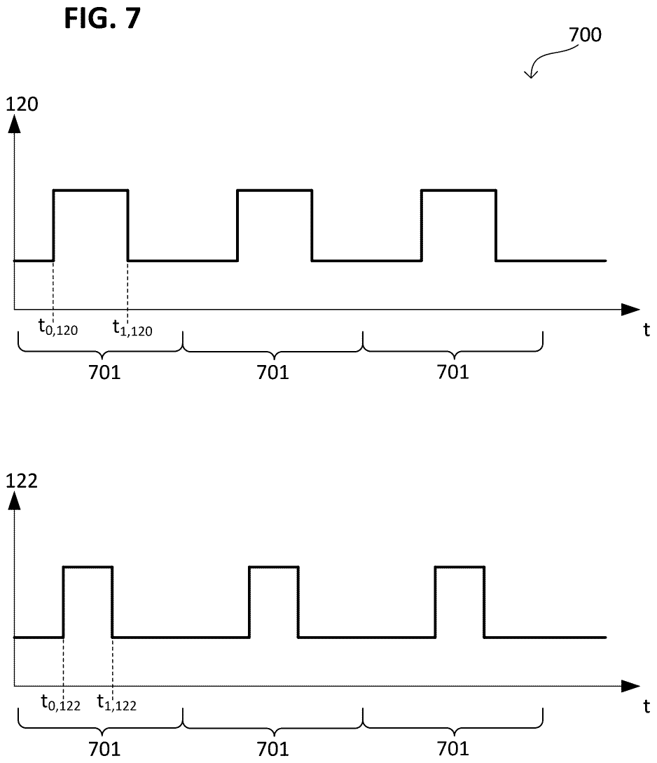

FIG. 7 shows an exemplary operating sequence 700 with a schematic timing diagram of the first electrical power pulse 120 and the second electrical power pulse 122, wherein the generation of the power pulse over time t is shown.

The operating sequence 700 may have several phases 701. In each phase 701, a first electrical power pulse 120 and a second electrical power pulse 122 may be generated.

Each electrical power pulse may be generated (e.g., according to a target time delay and a target pulse duration) such that it includes a start time, to, and an end time, t₁, the interval between which is specified as the pulse duration.

According to various aspects, the first electrical power pulse 120 (e.g., according to a first target time delay and a first target pulse duration) and the second electrical power pulse 122 (e.g., according to a second target time delay and a second target pulse duration) may be generated in a phase 701 such that they only partially overlap each other.

As explained herein, they overlap only partially, for example, if they start at different start times, t₀ (i.e., t_{0,120}≠t_{0,122}) and/or end at different end times, t₁ (i.e., t_{1,120}≠t_{1,122}). In this case, the pulse overlap is less than 1. A pulse overlap duration may be a time period between an overlap start time, t_{0,pulse overlap}, and an overlap end time, t_{1,pulse overlap}, where:

$${t}_{0 , Pulsüberdeckung} = ( \begin{matrix}{t}_{0 , 122} if {t}_{0 , 122} \geq {t}_{0 , 120} \\ {t}_{0 , 120} if {t}_{0 , 122} < {t}_{0 , 120}\end{matrix} )$$

$${t}_{1 , Pulsüberdeckung} = ( \begin{matrix}{t}_{0 , 122} if {t}_{0 , 122} \leq {t}_{0 , 120} \\ {t}_{0 , 120} if {t}_{0 , 122} > {t}_{0 , 120}\end{matrix} ) .$$

As explained herein, the reference time point of a phase may be the start of the phase. The target time delay described herein may be illustratively a target time difference from the reference time point of a phase (e.g., the start of the phase).

In the operating sequence 700 shown as an example in FIG. 7, the first electrical power pulse 120 in each phase 701 is generated at the reference time point of the clock generator (i.e., according to a first target time delay=0), and the second electrical power pulse 122 is generated in each phase 701 according to a (second) target time delay after the reference time of the clock generator (i.e., according to a second target time delay >0). Furthermore, in this exemplary operating sequence 700, the first electrical power pulse 120 is generated according to a first target pulse duration and the second electrical power pulse 122 is generated according to a second target pulse duration that is smaller than the first target pulse duration (and smaller than the difference between the first target pulse duration and the second target time delay, so that the second electrical power pulse 122 ends before the first electrical power pulse 120). Thus, the second target time delay may be greater than the first target time delay, and the second target pulse duration (=t_{1,122}−t_{0,122}) may be less than the first target pulse duration (=t_{1,120}−t_{0,120}).

According to various aspects, omitting individual second electrical power pulses 122 and reducing the pulse overlap between the first electrical power pulse 120 and the second electrical power pulse 122 may be combined to significantly increase the critical coating rate. In this case, the increase in the schematic rate-temperature curve 206 (see FIG. 2B) would be significantly reduced, so that the critical temperature, T_{c}, would be reached at a significantly higher critical rate, R_{c2}.

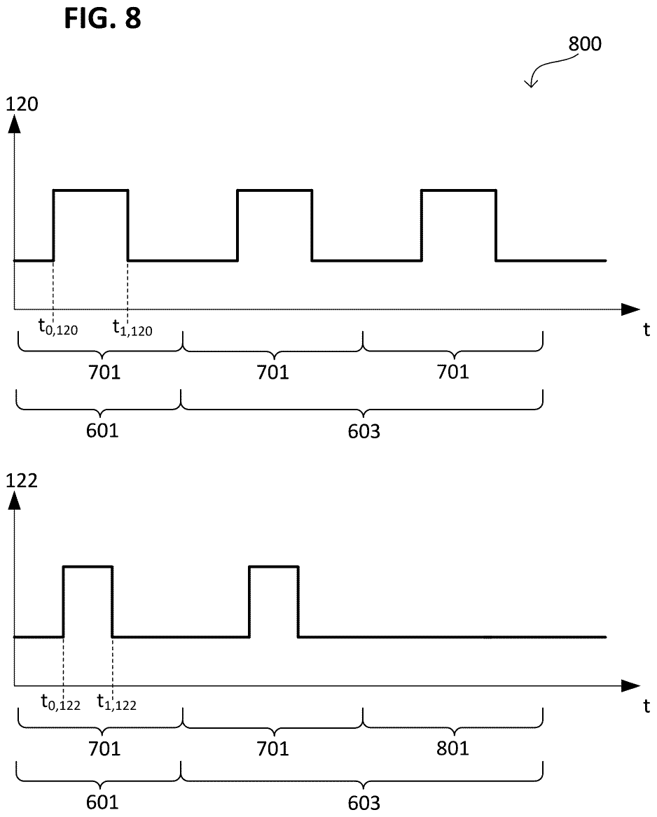

FIG. 8 shows an exemplary operating sequence 800 with a schematic time diagram of the first electrical power pulse 120 and the second electrical power pulse 122, wherein the first electrical power pulse 120 and the second electrical power pulse 122 are generated in phases 701, and wherein the first electrical power pulse 120 is generated but the second electrical power pulse 122 is not generated (i.e., omitted) in a phase 801.

If an electrical power pulse is measured, the start time, to, and the end time, t₁, of the electrical power pulse may be determined, for example, on the basis of a threshold value. FIG. 9 shows the time curve of the voltage and current of an exemplary power pulse 900a with a peak value V₍ₘₐₓ₎ of the voltage and peak value I₍ₘₐₓ₎ of the current. The threshold value (Vₜₕ or Iₜₕ) may be a predefined proportion (e.g., 10% or less, e.g., 5% or less) of the peak value Vₘₐₓ or Iₘₐₓ. In this case, the pulse width is the time difference between the two points in time t₀ and t₁ at which the time curve reaches the threshold value.

The target pulse length of the (e.g., first) power pulse may generally be in a range from approximately 30 μs to approximately 600 μs. In this regard, it has been recognized that when this target pulse length, l(p), (and thus essentially the pulse length of the first electrical power pulse 120) is in a range of approximately 250 μs to approximately 350 μs, the surface contact resistance, ICR, of the formed layer (e.g., in the case of carbon layers) is reduced. This is illustrated schematically in diagram 208a in FIG. 2C. The use of a target pulse length of the first electrical power pulse 120 in the range of approximately 250 μs to approximately 350 μs may, in the case of carbon arc evaporation, result in the formation of both singly charged and doubly charged carbon ions. In this regard, it has been recognized that this promotes layer formation and may therefore lead to a reduction in surface contact resistance, ICR. It is understood that the pulse length depends on the gradient of the rising edge and the falling edge of the pulse, so that a target gradient may also represent the target pulse length.

In diagram 208b, curve 210 refers to a layer produced using a target pulse length of the first electrical power pulse 120 in the range from approximately 250 μs to approximately 350 μs. It is illustratively shown that the reduction in surface contact resistance, ICR, results in the target contact resistance, ICR*, only being reached (or exceeded) at a higher critical temperature, T_{c2}. Consequently, in this case too, the (e.g., dynamic) coating rate may be increased with little risk of damage to the carbon layer.

Depending on various aspects, omitting individual second electrical power pulses 122 and/or reducing the pulse overlap may be combined with selecting the target pulse length of the first electrical power pulse 120 from the range of approximately 250 μs to approximately 350 us in order to further increase the critical coating rate.

In general, the coating rate may be increased by increasing the pulse frequency and/or the pulse length of the first electrical power pulse 120. If the pulse length of the first electrical power pulse 120 is selected from the above range, the coating rate may be increased by increasing the pulse frequency of the first electrical power pulse 120.

According to various aspects, omitting individual second electrical power pulses 122 and/or selecting the target pulse length of the first electrical power pulse 120 from the range of approximately 250 μs to approximately 350 μs may facilitate the production of a carbon layer on a substrate that includes one or more of the properties specified in examples 38 to 47.

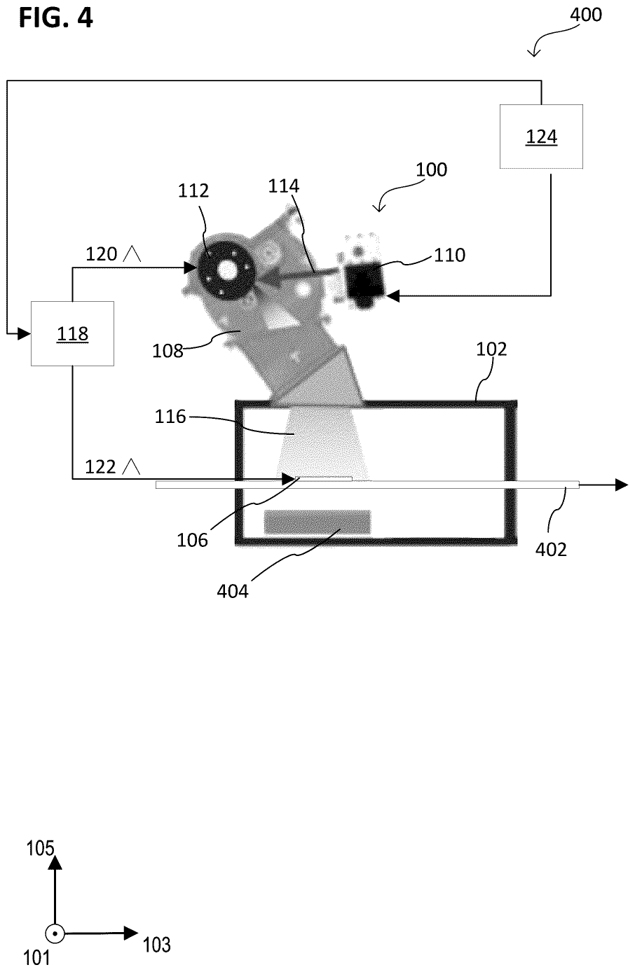

As described herein, laser-induced arc evaporation may be used to coat a substrate in a continuous flow system. FIG. 4 shows an exemplary vacuum chamber assembly 400 for coating by laser-induced arc evaporation in a continuous flow system according to various embodiments in a schematic top view or schematic side view. The vacuum chamber assembly 400 may include a transport device 402. The transport device 402 may be configured to transport the substrate 106 along a transport path (e.g., in transport direction 101) past the coating device 108. Optionally, the vacuum chamber assembly 400 may comprise a cooling element 404 (e.g., a cooling plate) for cooling the substrate 106. Cooling the substrate 106 by the cooling element may, for example, further increase the critical coating rate, R_{c}.

In this case, the transport device 402 and the vacuum arrangement 100 may be controlled in such a way that the coating rate at which the layer is formed on the substrate 106 (e.g., a carbon layer on a bipolar plate) is greater than or equal to 50 nm·m/min.

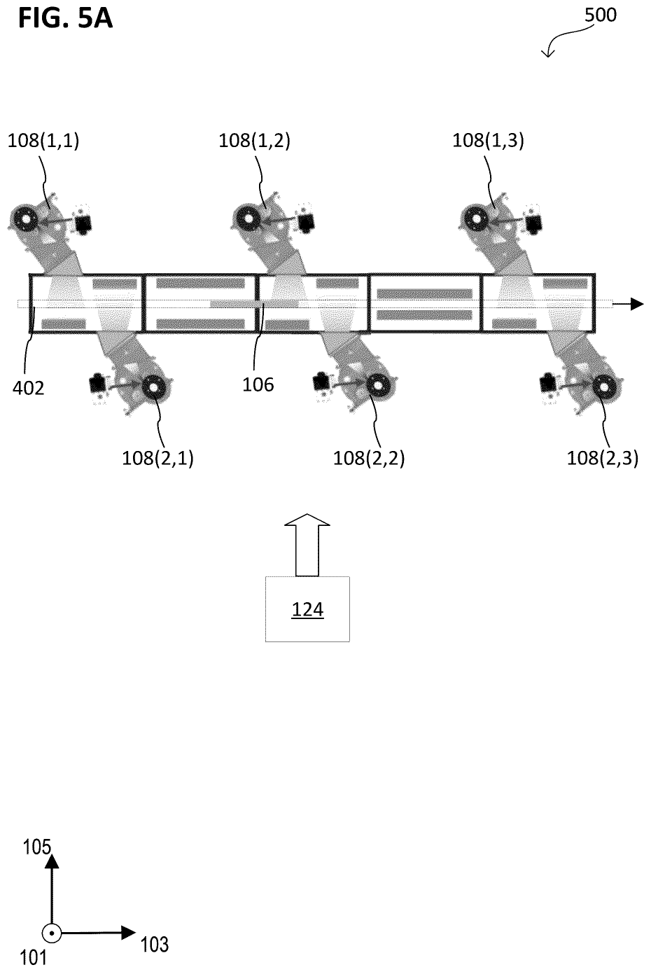

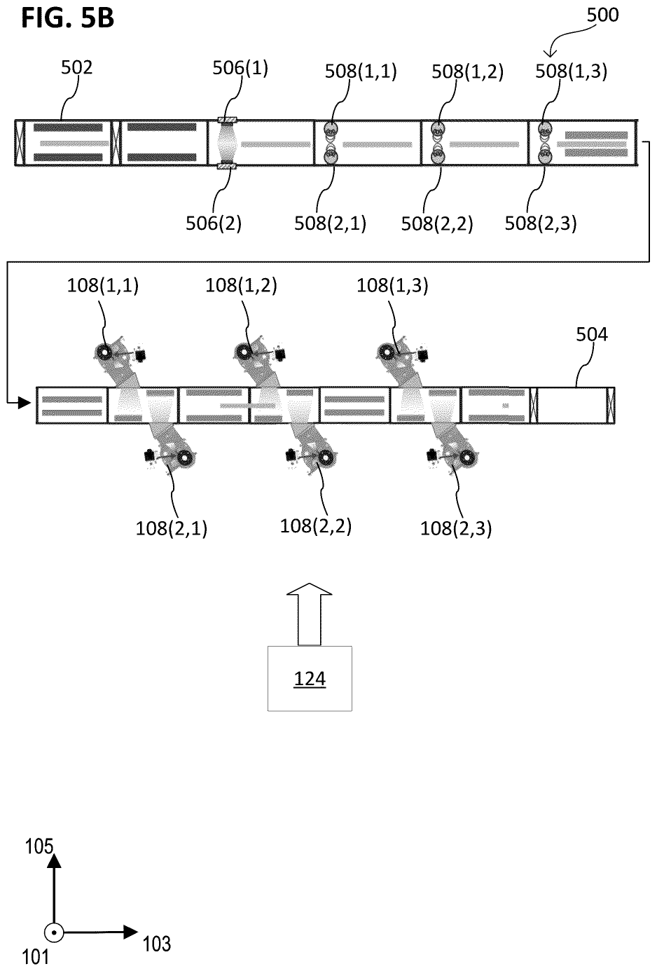

FIG. 5A and FIG. 5B show an exemplary continuous flow system 500 with multiple coating devices 108 according to different embodiments in a schematic top view.

As shown in FIG. 5A, in the continuous flow system 500, at least one substrate 106 may be passed by the transport device 402 past a plurality of coating devices 108(k, m). Coating devices 108(k, m) may be disposed on both sides of the transport path (e.g., on the left with k=1 and on the right with k=2 relative to the transport direction 101). For example, M coating devices 108 may be disposed on each side of the transport path, where M may be any integer greater than or equal to one. A coating device 108(k, m) may therefore be specified by the integers k and m (with 1≤m≤M).

For example, the at least one substrate 106 may be configured in a carrier which may be transported along the transport path by the transport device 402. The second electrical power pulse 122 described herein may be applied to this carrier in some embodiments.

According to various aspects, one coating device (k*, m*) of the plurality of coating devices may have a first (e.g., dynamic) coating rate, and another coating device 108(k*, m \m*) of the plurality of coating devices may have a second coating rate different from the first coating rate. For example, a first carbon 108 layer may be formed over the substrate 106 with a coating rate of less than 50 nm·m/min using a first coating device 108(1, 1), and a second carbon layer may then be formed on the first carbon layer with a coating rate greater than or equal to 50 nm m/min using a second coating device 108(1, 2) may then be used to form a second carbon layer on the first carbon layer with a coating rate greater than or equal to 50 nm·m/min. For example, in this case, the first carbon layer may serve as a nucleation layer for the second carbon layer. Optionally, in connection with the last coating device 108(k, 3), a higher peak power (e.g., peak voltage) of the second electrical power pulse 122 (compared to the other coating devices 108(k, m \3)) may be used. This may serve to break material peaks of the formed layer in order to smooth the layer.

In general, the continuous flow system 500 may have two substrate transfer openings through which the (at least one) substrate 106 may be fed into and out of the continuous flow system 500. Several processing areas may be configured between these two substrate transfer openings. For example, one or more of the processing areas may each have one or more coating devices 108. Consequently, the coating devices 108(k, m) shown in FIG. 5A may, for example, form three processing areas (wherein the substrate 106 may be coated on both sides in each processing area).

FIG. 5B shows an exemplary configuration of the continuous flow system 500 with several processing areas between a first substrate transfer opening 502 for feeding at least one substrate 106 (e.g., a bipolar plate) into the continuous flow system 500 and a second substrate transfer opening 502 for guiding the at least one substrate 106 out of the continuous flow system 500. There may be a vacuum in the continuous flow system 500.

The flow-through system 500 may have at least one plasma source 506(k) for plasma etching a surface of the substrate 106 (e.g., the bipolar plate). For example, the throughput system 500 may include a first plasma source 506(1) and a second plasma source 506(1) for plasma etching both sides of the substrate 106. The plasma etching may be performed, for example, using argon ion bombardment (e.g., by magnetron sputter etching, by inverse etching, or by processing with an argon ion source).

Optionally, the substrate 106 (e.g., the bipolar plate) may be heated (e.g., warmed) after plasma etching and then cooled.

Optionally, the continuous flow system 500 may have one or more coating sources 508(k, o) in addition to the coating devices 108(k, m). These may also be disposed on both sides of the transport direction 101.

A coating source 508(k, o) may, for example, be a coating source for magnetron sputtering, arc evaporation, or high-pulse magnetron sputtering.

In an exemplary process, a bipolar plate may be coated on both sides as a substrate in the continuous production line 500. The bipolar plate may, for example, have a surface roughness with a mean arithmetic height of less than or equal to 0.3 μm, preferably less than or equal to 0.2 μm, and/or a maximum height of less than or equal to 4.0 μm, preferably less than or equal to 2.5 μm. In the exemplary method, the surface of the bipolar plate may be cleaned on both sides using the first plasma source 506(1) and the second plasma source 506(1).

Then, one or more metal layers may be formed on the (cleaned surface of the) bipolar plate using the multiple coating sources 508(k, o). A metal layer may be, for example, a titanium layer. For example, a first metal layer may be formed on the bipolar plate using a first pair of coating sources 508(k, 1), and a second metal layer may be formed on the first metal layer using a second pair of coating sources 508(k, 2).(k, 1) may be used to form a first metal layer on the bipolar plate, a second pair of coating sources 508(k, 2) may be used to form a second metal layer on the first metal layer, and a third pair of coating sources 508(k, 3) may be used to form a third metal layer on the second metal layer.

In one example, the first metal layer, the second metal layer, and the third metal layer may each be a titanium layer or may form a common titanium layer. The common titanium layer may have a layer thickness in a range of approximately 20 nm to approximately 400 nm, preferably in a range of approximately 50 nm to approximately 150 nm. It is understood that the three metal layers are exemplary and that fewer metal layers (e.g., one or two) or more than three metal layers may also be formed (and the continuous flow system 500 may have corresponding coating sources). The (common) titanium layer may, for example, increase the corrosion resistance of the bipolar plate.

Then, the layer described herein (e.g., as a carbon layer) may be formed on the (common) titanium layer by the coating devices 108(k, m). Also, regarding the coating devices 108(k, m), it is understood that the number of coating devices shown is exemplary and that the continuous flow system 500 may also have more or fewer coating devices 108(k, m). For example, in some embodiments, one-sided processing of the substrate may be performed (so that k=1). As explained herein, (by omitting individual second electrical power pulses 122 and/or by selecting the target pulse length of the first electrical power pulse 120 from the range of approximately 250 μs to approximately 350 μs), a carbon layer may be formed, for example, which includes one or more of the properties specified in examples 38 to 47.

Optionally, the continuous flow system 500 may have one or more cooling zones (e.g., between two successive processing zones) to reduce the temperature of the substrate (and thus of the layer already formed). A cooling zone may, for example, comprise cooling plates or another suitable type of cooling.

While the layer (e.g., the carbon layer) is produced in the continuous processing system according to the principles described herein, it is understood that the layer may also be produced in other systems, such as drum coater systems.

FIG. 6 shows an exemplary operating sequence 600 in a schematic diagram in which the power P is represented as an exemplary time-dependent variable of the pulses over time t.

The operating sequence 600 includes several phases 601, 603, in each of which at least one laser pulse 114, at least one first electrical power pulse 120, and at most one second electrical power pulse 122 are generated. The multiple phases 601, 603 comprise a series (also referred to as a phase series) of multiple (e.g., two, three, or four) immediately successive phases 601 of a first type. In each phase 601 of the first type, exactly one laser pulse 114, exactly one first electrical power pulse 120, and exactly one second electrical power pulse 122 are generated. The multiple phases 601, 603 have one or more phases 603 of a second type, which are arranged between two immediately successive phase series and in which exactly two laser pulses 114, exactly two first electrical power pulses 120, and exactly one second electrical power pulse 122 are generated. It may be understood that the pulse numbers are exemplary.

1-14. (canceled)

15. A method, comprising:
controlling an excitation source according to an operating sequence;
controlling an electrical power source according to the operating sequence; wherein the operating sequence comprises a plurality of phases, in each phase thereof:
an excitation pulse directed at a target is generated by the excitation source to excite a plasma discharge at the target;
a first electrical power pulse is generated by the electrical power source to electrically supply the plasma discharge by the target; and,
a second electrical power pulse is generated by the electrical power source to accelerate a stream of material released from the target by the plasma discharge away from the target and toward a substrate holder; wherein the plurality of phases comprise one or more than one first phase, in which the first electrical power pulse and an electrical current pulse associated with the second electrical power pulse overlap each other only partially.

16. The method according to claim 15, wherein the plurality of phases comprises at least one second phase, in which two excitation pulses are generated per second electrical power pulse.

17. The method according to claim 15, wherein an electrical current pulse associated with the first electrical power pulse comprises an asymmetrical pulse shape.

18. The method according to claim 15, wherein an electrical current pulse associated with the first electrical power pulse comprises a peak value that is reached after half of a pulse duration of the electrical current pulse.

19. The method according to claim 15, wherein the current pulse associated with the second electrical power pulse begins after an electrical current pulse associated with the first electrical power pulse.

20. The method according to claim 15, wherein an electrical voltage pulse associated with the second electrical power pulse begins after an electrical current pulse associated with the first electrical power pulse.

21. The method according to claim 15, wherein the first electrical power pulse is generated according to a target voltage pulse duration.

22. The method according to claim 15, wherein an electrical current pulse associated with the first electrical power pulse comprises a triangular pulse shape.

23. The method according to claim 15, wherein the target and the plasma discharge are exposed to at least hydrogen.

24. The method according to claim 15, wherein the electrical power source comprises an output filter which is configured to be controlled in response to the desired pulse shape in order to influence a time dependence of an electrical current pulse associated with the first electrical power pulse.

25. The method according to claim 15, wherein the first electrical power pulse is transmitted by the target and an anode associated with the target; and
wherein the second electrical power pulse is transmitted by a substrate holder onto which the material flow is directed or an anode associated with the substrate holder.

26. The method according to claim 15, wherein the target comprises or consists of carbon.

27. The method according to claim 15, wherein in each of the one or more second phases:
an electrical current pulse associated with the first electrical power pulse is generated according to a first target time distance from a start of the second phase, and wherein an electrical current pulse associated with the second electrical power pulse is generated according to a second target time distance from the start of the second phase, wherein the second target time distance is greater than the first target time distance.

28. The method according to claim 15, further comprising:
updating the operating sequence based on a result of the plasma discharge.

29. The method according to claim 15, further comprising:
exposing a bipolar plate to a vacuum; and,
performing laser-induced arc evaporation in the vacuum by controlling the excitation source and the electrical power source, wherein the material flow released by the plasma discharge comprises carbon and is emitted toward the bipolar plate.

30. Method according to claim 29, wherein the vacuum is provided by a vacuum chamber, which comprises two substrate transfer openings through which the bipolar plate is transported and between which a coating area is configured into which the material flow is emitted.

31. Method according to claim 30, wherein the controlling and the transporting are further configured relative to each other such that a rate at which the carbon layer is formed on the bipolar plate is greater than or equal to 50 nm·m/min.

32. A non-transitory storage medium storing instructions configured, when executed by a processor, to cause the processor to perform the following:
controlling an excitation source according to an operating sequence;
controlling an electrical power source according to the operating sequence; wherein the operating sequence comprises a plurality of phases,
in each phase thereof:
an excitation pulse directed at a target is generated by the excitation source to excite a plasma discharge at the target;
a first electrical power pulse is generated by the electrical power source to electrically supply the plasma discharge by the target; and,
a second electrical power pulse is generated by the electrical power source to accelerate a stream of material released from the target by the plasma discharge away from the target and toward a substrate holder; wherein the plurality of phases comprise one or more than one first phase, in which the first electrical power pulse and an electrical current pulse associated with the second electrical power pulse overlap each other only partially.

33. A device comprising one or more processors configured to perform to perform the following:
controlling an excitation source according to an operating sequence;
controlling an electrical power source according to the operating sequence; wherein the operating sequence comprises a plurality of phases, in each phase thereof:
an excitation pulse directed at a target is generated by the excitation source to excite a plasma discharge at the target;
a first electrical power pulse is generated by the electrical power source to electrically supply the plasma discharge by the target; and,
a second electrical power pulse is generated by the electrical power source to accelerate a stream of material released from the target by the plasma discharge away from the target and toward a substrate holder; wherein the plurality of phases comprise one or more than one first phase, in which the first electrical power pulse and an electrical current pulse associated with the second electrical power pulse overlap each other only partially.

34. The device of claim 33, further comprising:
the power source;
the excitation source; and,
a target holder for holding the target, wherein the target holder is electrically coupled to the power source; wherein the target holder provides a rotational axis and is configured to cause the target to rotate about the rotational axis.
